(19) United States
(12) Patent Application Publication
(10) Pub. No.: US 2025/0266398 A1
(43) Pub. Date: Aug. 21, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Hyunsoo Chung, Suwon-si (KR)

(21) Appl. No.: 18/950,909

(22) Filed: Nov. 18, 2024

(30) Foreign Application Priority Data
Feb. 16, 2024 (KR) 10-2024-0022230

(51) Int. Cl. H01L 25/065; H01L 23/06

(52) U.S. Cl. CPC H01L 25/0657; H01L 23/06; H01L 2225/06541

(57) ABSTRACT

A semiconductor package includes a buffer die, a plurality of core die blocks sequentially stacked on the buffer die, a top core die on an uppermost core die block of the plurality of core die blocks, and a molding member surrounding outer side surfaces of the plurality of core die blocks and the top core die on the buffer die. Each of the core die blocks includes a plurality of core dies sequentially stacked, and a plurality of gap filling portions surrounding outer side surfaces of at least two stages of core dies of the plurality of core dies. Outer side surfaces of the plurality of gap filling portions of each of the plurality of core die blocks are coplanar.

### PRIORITY STATEMENT

This application claims priority under 35 U.S.C. § 119 to Korean Patent Application No. 10-2024-0022230, filed on Feb. 16, 2024 in the Korean Intellectual Property Office (KIPO), the contents of which are herein incorporated by reference in their entirety.

### FIELD

Example embodiments relate to a semiconductor package and a method of manufacturing the semiconductor package. More particularly, example embodiments relate to a semiconductor package including a plurality of sequentially stacked semiconductor chips and a method of manufacturing the same.

### BACKGROUND

To manufacture a multi-chip package in which at least sixteen semiconductor chips are stacked, core dies may be attached to a buffer die on a carrier substrate by a die-to-wafer bonding method. In the die-to-wafer bonding method, as a thickness of the stacked core dies decreases, warpage increases and process difficulty increases, making it difficult to stack core dies with a thickness of about 30 μm or less at a high level (e.g., an ultra-high level). In addition, as the number of the stacked core dies increases, the interfacial bonding quality deteriorates and the yield decreases.

### SUMMARY

Example embodiments provide a semiconductor package having improved bonding quality and including stacked dies at a high level (e.g., an ultra-high-level).

Example embodiments provide a method of manufacturing the semiconductor package.

According to example embodiments, a semiconductor package includes a buffer die, a plurality of core die blocks sequentially stacked on the buffer die, a top core die on an uppermost core die block of the plurality of core die blocks, and a molding member surrounding outer side surfaces of the plurality of core die blocks and the top core die on the buffer die. Each of the core die blocks includes a plurality of core dies sequentially stacked, and a plurality of gap filling portions surrounding outer side surfaces of at least two stages of core dies of the plurality of core dies. Outer side surfaces of the plurality of gap filling portions of each of the plurality of core die blocks are coplanar.

According to example embodiments, a semiconductor package includes a buffer die, a plurality of core die blocks sequentially stacked on the buffer die, each of the plurality of core die blocks including a plurality of die structures that are sequentially stacked, and a sealing member surrounding outer side surfaces of the plurality of core die blocks on the buffer die. Each of the plurality of die structures includes a substrate, a front insulating layer on a front surface of the substrate and including a first bonding pad therein, a backside insulating layer on a backside surface of the substrate and including a second bonding pad therein, and a gap filling portion surrounding outer side surfaces of the substrate and the front insulating layer.

According to example embodiments, a semiconductor package includes a buffer die, a plurality of core die blocks sequentially stacked on the buffer die, and a sealing member on outer side surfaces of the plurality of core die blocks on the buffer die. Each of the plurality of core die blocks includes a plurality of core dies sequentially stacked, and a plurality of gap filling portions on outer side surfaces of at least two stages of core dies of the plurality of core dies.

According to example embodiments, a semiconductor package may include a plurality of core die blocks sequentially stacked on a buffer die, and a molding member that is on, covers, or surrounds outer side surfaces of the plurality of core die blocks. Each of the core die blocks may include a plurality of core dies sequentially stacked, and a plurality of gap filling portions on, covering, or surrounding outer side surfaces of at least two stages of core dies of the plurality of core dies. Outer side surfaces of the plurality of gap filling portions of each of the plurality of core die blocks may be coplanar.

The semiconductor package may include the plurality of sequentially stacked core die blocks that are made of module blocks respectively. An ultra-high-end HBM may be implemented by forming the core die block having the core dies stacked using a die-to-wafer bonding method and sequentially stacking the core die blocks on the buffer die. Since the core die blocks are stacked in module units, it may be possible to stack the core dies having a thickness of about 30 μm or less at an extremely high level. Further, since the core dies and the core die blocks are each bonded by a hybrid bonding method, a total thickness may be reduced and heat dissipation characteristics may be improved.

### BRIEF DESCRIPTION OF THE DRAWINGS

Example embodiments will be more clearly understood from the following detailed description taken in conjunction with the accompanying drawings. FIGS. 1 to 34 represent non-limiting, example embodiments as described herein.

FIG. 1 is a cross-sectional view illustrating a semiconductor package in accordance with example embodiments.

FIG. 2 is a cross-sectional view illustrating a core die block of the semiconductor package in FIG. 1.

FIG. 3 is an enlarged cross-sectional view illustrating portion ‘A’ in FIG. 1.

FIG. 4 is an enlarged cross-sectional view illustrating portion ‘B’ in FIG. 1.

FIGS. 5 to 23 are views illustrating a method of manufacturing a semiconductor package in accordance with example embodiments.

FIG. 24 is a cross-sectional view illustrating a semiconductor package in accordance with example embodiments.

FIG. 25 is a cross-sectional view illustrating a core die block of the semiconductor package in FIG. 24.

FIGS. 26 to 34 are views illustrating a method of manufacturing a semiconductor package in accordance with example embodiments.

### DETAILED DESCRIPTION

Hereinafter, example embodiments will be explained in detail with reference to the accompanying drawings.

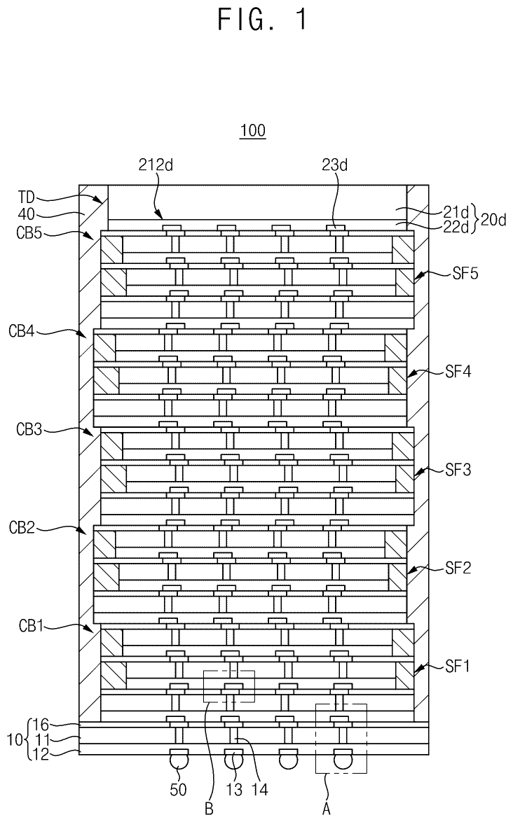

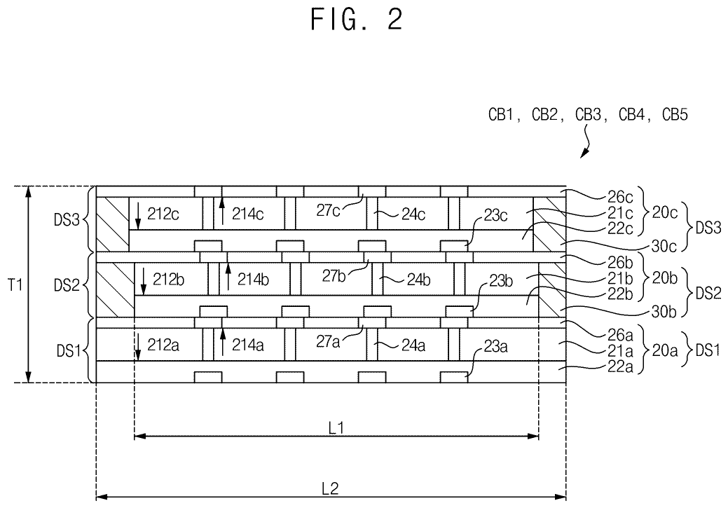

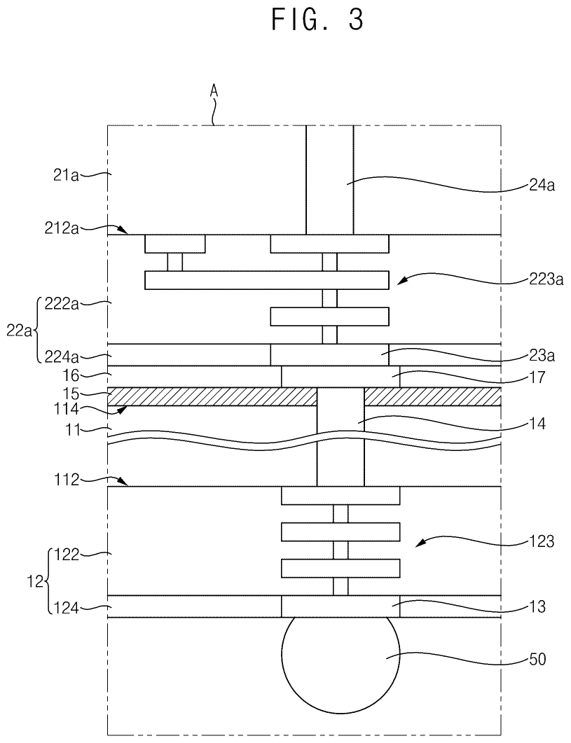

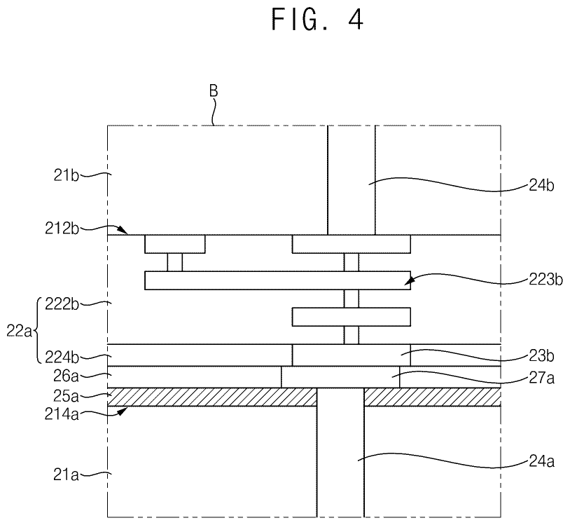

FIG. 1 is a cross-sectional view illustrating a semiconductor package in accordance with example embodiments. FIG. 2 is a cross-sectional view illustrating a core die block of the semiconductor package in FIG. 1. FIG. 3 is an enlarged cross-sectional view illustrating portion ‘A’ in FIG. 1. FIG. 4 is an enlarged cross-sectional view illustrating portion ‘B’ in FIG. 1.

Referring to FIGS. 1 to 4, a semiconductor package 100 may include semiconductor chips (dies) stacked therein. The semiconductor package 100 may include a buffer die 10 and a plurality of core die blocks CB1, CB2, CB3, CB4, CB5 sequentially stacked on the buffer die 10. Each of the core die blocks CB1, CB2, CB3, CB4, CB5 may include a plurality of die structures DS1, DS2, DS33 sequentially stacked. Each of the core die blocks CB1, CB2, CB3, CB4, CB5 may include a plurality of core dies 20a, 20b, 20c sequentially stacked on one another and a plurality of gap filling portions 30b, 30c covering or surrounding outer side surfaces of at least two stages of core dies 20b, 20c of the plurality of core dies 20a, 20b, 20c, respectively. Additionally, the semiconductor package 100 may further include a top core die stack TD stacked on an uppermost core die block CB5 among the plurality of core die blocks CB1, CB2, CB3, CB4, CB5, and a molding member or sealing member 40 that covers or surrounds outer side surfaces of the plurality of core die blocks CB1, CB2, CB3, CB4, CB5.

Each of the core die blocks may include a plurality of semiconductor chips (dies) 20a, 20b, 20c that are stacked vertically. In example embodiments, the semiconductor chips (dies) 20a, 20b, 20c may be substantially the same as or similar to each other. Accordingly, same or like reference numerals will be used to refer to the same or like elements and repeated descriptions of the same elements may be omitted in the interest of brevity.

The number of the core die blocks sequentially stacked on the buffer die 10 may be determined depending on the total number of the core dies stacked on the buffer die 10 and the number of the core dies in each core die block. One core die block may include at least two core dies stacked.

In example embodiments, the semiconductor package as a multi-chip package is as illustrated as including sixteen stacked semiconductor chips 20a, 20b, 20c on the buffer die 10, however, it may not limited thereto. For example, the semiconductor package may include 20 or 24 stacked semiconductor chips.

Each of the semiconductor chips 20a, 20b, 20c may include an integrated circuit chip completed by performing semiconductor manufacturing processes. Each semiconductor chip may include, for example, a memory chip or a logic chip. The semiconductor package 100 may include a memory device. The memory device may include a high bandwidth memory (HBM) device.

As illustrated in FIG. 2, each of first, second, third, fourth and fifth core die blocks CB1, CB2, CB3, CB4 and CB5 may include first, second and third die structures DS1, DS2 and DS3 sequentially stacked. The first die structure DS1 may include a first core die 20a. The second die structure DS2 may include a second core die 20b and a gap filling portion or member 30b that covers or surrounds an outer side surface of the second core die 20b. The third die structure DS3 may include a third core die 20c and a gap filling portion or member 30b that covers or surrounds an outer side surface of the third core die 20c. Each of the core die blocks may include the first, second and third core dies 20a, 20b, and 20c sequentially stacked, and the gap filling portions 30b, and 30c respectively covering or surrounding the outer side surfaces of the second, and third core dies 20b, and 20c stacked in at least two stages. In example embodiments, one core die block CB1, CB2, CB3 may include the core dies 20a, 20b, and 20c stacked in three stages, but it will be understood that the present inventive concept is not limited thereto.

The first, second, third, fourth and fifth core die blocks CB1, CB2, CB3, CB4 and CB5 may be substantially identical to each other. Each of the first, second, third, fourth and fifth core die blocks CB1, CB2, CB3, CB4 and CB5 may have a rectangular parallelepiped shape. A lower surface of the first die structure DS1 may serve as a lower surface of each core die block, and an upper surface of the third die structure DS3 may serve as an upper surface of each core die block.

In example embodiments, the first, second, third, fourth and fifth core die blocks CB1, CB2, CB3, CB4 and CB5 may be sequentially stacked on the buffer die 10. The first core die blocks CB1 may be bonded to a wafer including the buffer die 10 by hybrid bonding. The second core die block CB2 may be bonded to the first core die block CB1. Accordingly, misalignment may occur between the first core die block CB1 and the second core die block CB2, and an outer side surface SF1 of the first core die block CB1 and an outer side surface SF2 of the second core die block CB2 may be positioned on different planes, respectively. Similarly, the third core die block CB3 may be bonded to the second core die block CB2. Accordingly, misalignment may occur between the second core die block CB2 and the third core die block CB3, and the outer side surface SF2 of the second core die block CB2 and an outer side surface SF3 of the third core die block CB3 may be positioned on different planes, respectively. Similarly, the fourth core die block CB4 may be bonded to the third core die block CB3. Accordingly, misalignment may occur between the third core die block CB3 and the fourth core die block CB4, and the outer side surface SF3 of the third core die block CB3 and an outer side surface SF4 of the fourth core die block CB4 may be positioned on different planes, respectively. Similarly, the fifth core die block CB5 may be bonded to the fourth core die block CB4. Accordingly, misalignment may occur between the fourth core die block CB4 and the fifth core die block CB5, and the outer side surface SF4 of the fourth core die block CB4 and an outer side surface SF5 of the fifth core die block CB5 may be positioned on different planes, respectively. A (horizontal) width of the buffer die 10 may be greater than a width of each of the first, second, third, fourth and fifth core die blocks CB1, CB2, CB3, CB4 and CB5.

Each core die block may have a thickness T1 of at least 40 μm. Each of the first to third core dies 20a, 20b, and 20c may have a thickness within a range of about 10 μm to 30 μm. The first core die 20a may have a first planar area, and the second and third core dies 20b and 20c may have a second planar area that is less than the first planar area. The first core die 20a may have a first (horizontal) width, and the second and third core dies 20b and 20c may have a second (horizontal) width less than the first width.

In example embodiments, the buffer die 10 may include a substrate 11, a front insulating layer 12, a plurality of first bonding pads 13, a plurality of through electrodes 14, a backside insulating layer 16, and a plurality of second bonding pads 17. Additionally, the buffer die 10 may further include conductive bumps 50 as conductive connection members respectively provided on the first bonding pads 13. The buffer die 10 may be mounted on a package substrate or an interposer via the conductive bumps 50. For example, the conductive bump 50 may include a solder bump. Alternatively, the conductive bump 50 may include a pillar bump and a solder bump formed on the pillar bump.

The substrate 11 may have a first surface 112 and a second surface 114 opposite to the first surface 112. The first surface 112 may be an active surface, and the second surface 114 may be a non-active surface. Circuit patterns may be provided on the first surface 112 of the substrate 11. The first surface 112 may be referred to as a front surface on which the circuit patterns are formed, and the second surface may be referred to as a backside surface.

For example, the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIG. 3, the front insulating layer 12 as an insulation interlayer may be formed on the first surface 112 of the substrate 11, that is, the front surface. The front insulating layer 12 may include a plurality of insulating layers 122 and 124 and wirings 123 in the insulating layers. Additionally, the first bonding pad 13 may be provided in an outermost or lowermost insulating layer of the front insulating layer 12.

For example, the front insulating layer 12 may include a metal wiring layer 122 and a first passivation layer 124. The metal wiring layer 122 may include a plurality of wirings 123 therein. For example, the metal wiring layer 122 may include a metal wiring structure including a plurality of wirings 123 vertically stacked in buffer layers and insulating layers. The first bonding pad 13 may be formed on a lowermost wiring among the plurality of wirings 123. For example, the wirings may include aluminum (Al), copper (Cu), tin (Sn), nickel (Ni), gold (Au), platinum (Pt), or an alloy thereof.

The first passivation layer 124 may be formed on the metal wiring layer 122 and may expose at least a portion of the first bonding pad 13. The first passivation layer 124 may include a plurality of stacked insulating layers. For example, the first passivation layer 124 may include a first protective layer including an oxide layer and a second protective layer including a nitride layer, sequentially stacked. The first protective layer may include silicon oxide, and the second protective layer may include silicon nitride or silicon carbonitride.

The first bonding pad 13 may be provided in the first passivation layer 124. The first bonding pad 13 may be exposed through an outer surface of the first passivation layer 124. An upper surface of the first bonding pad 13 may be coplanar with an upper surface of the first passivation layer 124 and/or a lower surface of the first bonding pad 13 may be coplanar with a lower surface of the first passivation layer 124. Although not illustrated in the figures, an insulation interlayer may be provided on the first surface 112 of the substrate 11 to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 13 by the lower wirings and the wirings.

The through electrode (e.g., through silicon via, TSV) 14 may vertically penetrate the insulation interlayer and may extend from the first surface 112 to the second surface 114 of the substrate 11. The through electrode 14 may contact an uppermost wiring of the metal wiring structure. Accordingly, the through electrode 24 may be electrically connected to the first bonding pad 13 by the wirings 123.

The backside insulating layer 16 may be formed on the second surface 114 of the substrate 11, that is, the backside surface. The second bonding pad 17 may be provided in the backside insulating layer 16. For example, the second bonding pad 17 may be disposed on an exposed surface of the through electrode 14. An upper surface of the second bonding pad 17 may be coplanar with an upper surface of the backside insulating layer 16 and/or a lower surface of the second bonding pad 17 may be coplanar with a lower surface of the backside insulating layer 16. The backside insulating layer 16 may include silicon oxide, carbon-doped silicon oxide, silicon carbonitride (SiCN), etc. Accordingly, the first and second bonding pads 13 and 17 may be electrically connected to each other by the through electrode 24

As illustrated in FIGS. 3 and 4, the first core die 20a of the first die structure CD1 of the first core die block CB1 may include a substrate 21a, a front insulating layer 22a, a plurality of first bonding pads 23a, a plurality of through electrodes 24a, a backside insulating layer 26a and a plurality of second bonding pads 27a.

The substrate 21a may have a first surface 212a and a second surface 214a opposite to the first surface 212a. The first surface 212a may be an active surface, and the second surface 214a may be a non-active side. Circuit patterns may be provided on the first surface 212a of the substrate 21a. The front insulating layer 22a as an insulation interlayer may be formed on the first surface 212a of the substrate 21a, that is, a front surface. The front insulating layer 22a may include a plurality of insulating layers 222a and 224a and wirings 223a in the insulating layers 222a and 224a. Additionally, the first bonding pad 23a may be provided in an outermost or lowermost insulating layer of the front insulating layer 22a. For example, the front insulating layer 22a may include a metal wiring layer 222a and a first passivation layer 224a. The metal wiring layer 222a may include a plurality of wirings 223a therein.

The through electrode 24a may extend vertically from the first surface 212a to the second surface 214a of the substrate 21a. The through electrode 24a may be electrically connected to the first bonding pad 23a by the wirings 223a. The backside insulating layer 26a may be formed on the second surface 214a of the substrate 21a, that is, a backside surface. The second bonding pad 27a may be provided in the backside insulating layer 26a. Accordingly, the first and second bonding pads 23a and 27a may be electrically connected to each other by the through electrode 24a.

Similarly, the second core die 20b of the second die structure CD2 may include a substrate 21b, a front insulating layer 22b, a plurality of first bonding pads 23b, a plurality of through electrodes 24b, a backside insulating layer 26b, and a plurality of second bonding pads 27b. Since the core dies 20a, 20b and 20c are substantially the same as or similar to each other, same or like reference numerals will be used to refer to the same or like elements and repeated descriptions of the same elements may be omitted in the interest of brevity.

The backside insulating layer 26b of the second die structure DS2 may protrude or extend inwardly in a horizontal direction from the outer side surfaces of the substrate 21b and the front insulating layer 22b. The substrate 21b and the front insulating layer 22b may have a length in a first direction, that is, a first width L1, and the backside insulating layer 26b may has a second width L2 greater than the first width L1. The substrate 21a may have the second width L2.

As illustrated in FIG. 3, the first core die 20a of the first core die block CB1 and the buffer die 10 may be bonded to each other by hybrid bonding. The second bonding pad 17 of the buffer die 10 and the first bonding pad 23a of the first core die 20a may be bonded to each other by copper-copper hybrid bonding (Cu—Cu Hybrid Bonding). A front surface of the first core die 20a, that is, the front side insulating layer 22a on the first surface 212a of the substrate 21a may be directly bonded to the backside insulating layer 16 of the substrate 11 of the buffer die 10.

As illustrated in FIG. 4, the second core die 20b and the first core die 20a may be bonded to each other by hybrid bonding. The second bonding pad 27a of the first core die 20a and the first bonding pad 23b of the second core die 20b may be bonded to each other by copper-copper hybrid bonding (Cu—Cu Hybrid Bonding).

The front insulating layer 22b on a front surface of the second core die 20b may be directly bonded to the backside insulating layer 26a on a backside surface of the first core die 20a. The outermost insulating layers of the backside insulating layer 26a and the front insulating layer 22b may include an insulating material that contacts each other and provides excellent bonding strength, thereby providing a bonding structure. The backside insulating layer 26a and the front insulating layer 22b may be bonded to each other by a high temperature annealing process while in contact with each other. Here, the bonding structure may have a relatively stronger bonding strength by covalent bonding.

Similarly, the third core die 20c and the second core die 20b may be bonded to each other by hybrid bonding.

The gap filling portion 30b of the second die structure DS2 may at least partially cover or surround the outer side surface of the second core die 20b. The gap filling portion 30b may cover or surround outer side surfaces of the substrate 21b and the front insulating layer 22b of the second core die 20b. The backside insulating layer 26b of the second core die 20b may cover an upper surface of the gap filling portion 30b. The backside insulating layer 26b may protrude or extend inwardly in a horizontal direction from the outer side surfaces of the substrate 21b and the front insulating layer 22b, and the protruding portion of the backside insulating layer 26b may cover the upper surface of the gap filling portion 30b. An outer side surface of the backside insulating layer 26b and an outer side surface of the gap filling portion 30b may be coplanar or positioned on the same plane.

For example, the gap filling portion 30b may be formed by a conformal deposition process such as an atomic layer deposition (ALD) process or a chemical vapor deposition (CVD) process. The gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

Alternatively, the gap filling portion 30b of the second die structure DS2 may cover or surround the entire outer side surface of the second core die 20b. The gap filling portion 30b of the second die structure DS2 may cover the outer side surfaces of the substrate 21b, the front insulating layer 22b, and the backside insulating layer 26b of the second core die 20b. In this case, the backside insulating layer 26b may not protrude in the horizontal direction from the outer side surfaces of the substrate 21b and the front insulating layer 22b, and the outer side surface of the backside insulating layer 26b and the outer side surfaces of the substrate 21b and the front insulating layer 22b may be coplanar or positioned on the same plane.

Similarly, the gap filling portion 30c of the third die structure DS3 may at least partially cover or surround the outer side surface of the third core die 20c. The gap filling portion 30c may cover or surround outer side surfaces of a substrate 21c and a front insulating layer 22c of the third core die 20c. A backside insulating layer 26c of the third core die 20c may cover an upper surface of the gap filling portion 30c. The backside insulating layer 26c may protrude or extend inwardly in a horizontal direction from the outer side surfaces of the substrate 21c and the front insulating layer 22c, and the protruding portion of the backside insulating layer 26c may cover the upper surface of the gap filling portion 30c. An outer side surface of the backside insulating layer 26c and the outer side surface of the gap filling portion 30c may be coplanar or positioned on the same plane.

The backside insulating layer 26a of the first die structure DS1 may cover or be on a lower surface of the gap filling portion 30b of the second die structure DS2. The backside insulating layer 26b of the second die structure DS2 may cover or be on a lower surface of the gap filling portion 30c of the third die structure RD3. Additionally, the outer side surfaces of the gap filling portions 30b, 30c of the first core die block CB1 may be coplanar or positioned on the same plane.

In example embodiments, the top core die stack TD may include a top core die 20d. The top core die 20d and the fifth core die block CB5 may be bonded to each other by hybrid bonding. A front surface of the top core die 20d, that is, a front side insulating layer 22d on a first surface 212d of a substrate 21d may be directly bonded to a backside insulating layer 26c of a third core die 20c of the fifth core die block.

A second bonding pad 27c of the third core die 20c of the fifth core die block and a first bonding pad 23d of the top core die 20d may make contact with each other. When the fifth core die block and the top core die 20d are bonded to each other by die-to-wafer bonding, the second bonding pad 27c of the third core die 20c of the fifth core die block and the first bonding pads 23d of the top core die 20d may be bonded to each other by copper-copper hybrid bonding (Cu—Cu Hybrid Bonding).

A thickness of the top core die 20d may be greater than thicknesses of the middle core dies 20a, 20b, and 20c. The thickness of the top core die 20d may be within a range of 50 μm to 300 μm.

In example embodiments, the molding member 40 (also referred to herein as the sealing member 40) may be provided to cover or surround outer side surfaces of the first, second, third, fourth and fifth core die blocks CB1, CB2, CB3, CB4 and CB5 and the top core die 20d. The molding member 40 may cover or surround outer side surfaces of the first to third die structures DS1, DS2 and DS3 of each of the first, second, third, fourth and fifth core die blocks CB1, CB2, CB3, CB4 and CB5. The molding member 40 may directly contact the gap filling portions 30b, 30c of the second and third die structures DS2 and DS3.

For example, the molding member 40 may include a molding material such as a thermosetting resin. The molding material may include an epoxy mold compound (EMC). The molding material may include UV resin, polyurethane resin, silicone resin, silica filler, etc.

As mentioned above, the semiconductor package 100 may include the first, second, third, fourth and fifth core die blocks CB1, CB2, CB3, CB4 and CB5 sequentially stacked on the buffer die 10, and the molding member 40 that covers or surrounds the outer side surfaces of the first, second, third, fourth and fifth core die blocks CB1, CB2, CB3, CB4 and CB5. Each of the first, second, third, fourth and fifth core die blocks CB1, CB2, CB3, CB4 and CB3 may include the first, second and third die structures DS1, DS2 and DS3 sequentially stacked. The first die structure DS1 may include the first core die 20a. The second die structure DS2 may include the second core die 20b and the gap filling portion 30b covering or surrounding the outer side surface of the second core die 20b. The third die structure DS3 may include the third core die 20c and the gap filling portion 30c covering or surrounding the outer side surface of the third core die 20c.

The semiconductor package 100 may include a plurality of the sequentially stacked first, second, third, fourth and fifth core die blocks CB1, CB2, CB3, CB4 and CB5 that are made of module blocks respectively. An ultra-high-end HBM may be implemented by forming the core die blocks each having the core dies stacked using a die-to-wafer bonding method and sequentially stacking the core die blocks on the buffer die 10. Since the core die blocks are stacked in module units, it may be possible to stack the core dies having a thickness of about 30 μm or less at an extremely high level. Further, since the core dies and the core die blocks are each bonded by a hybrid bonding method, a total thickness may be reduced and heat dissipation characteristics may be improved.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package in accordance with example embodiments is not limited thereto.

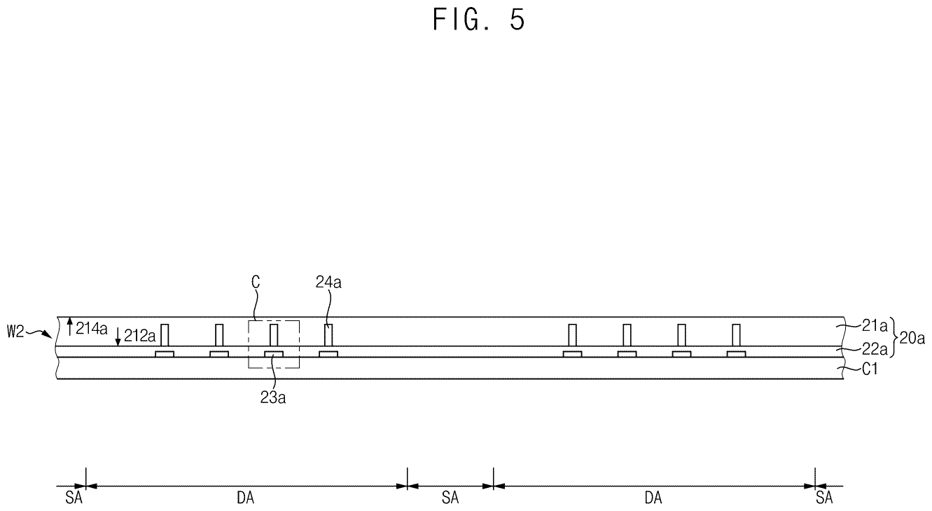

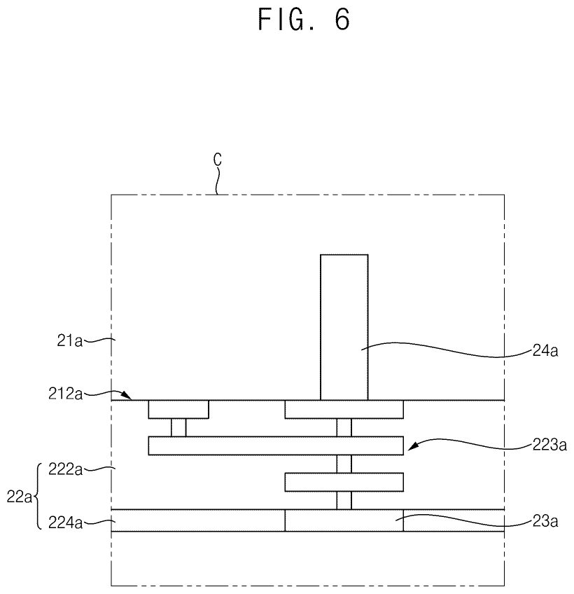

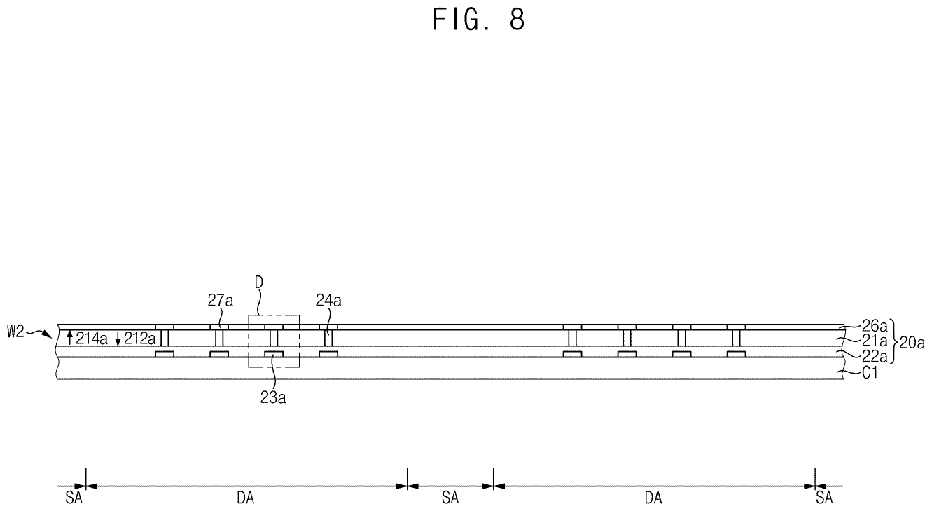

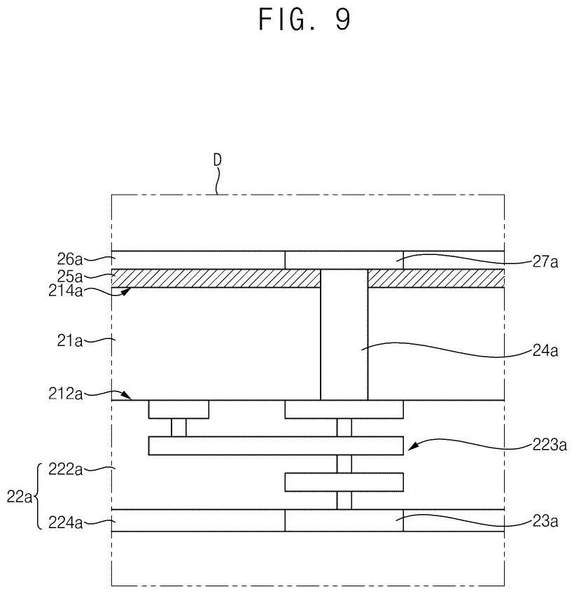

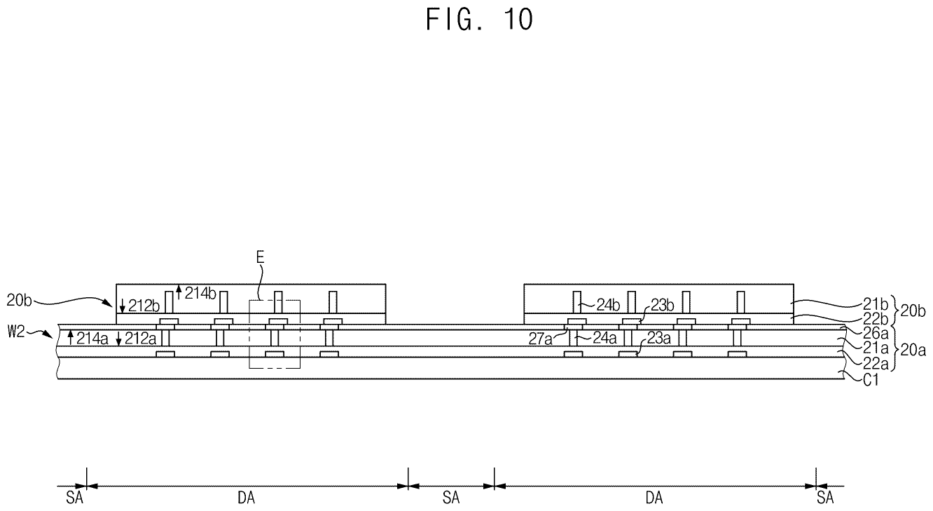

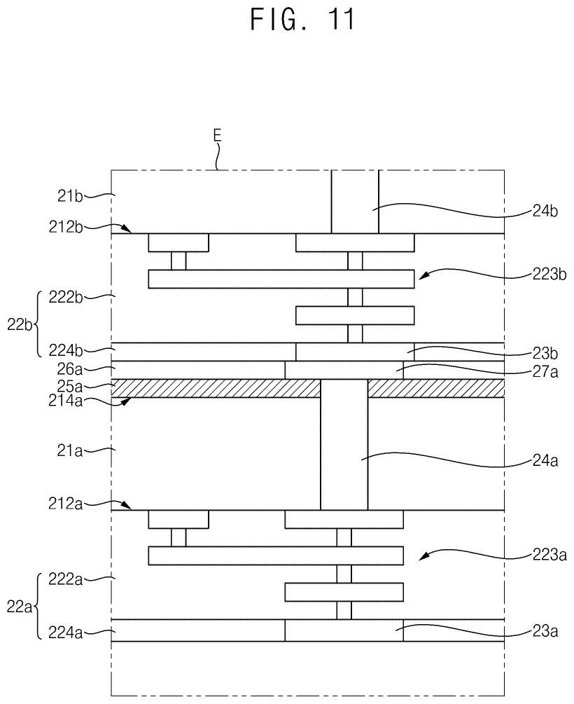

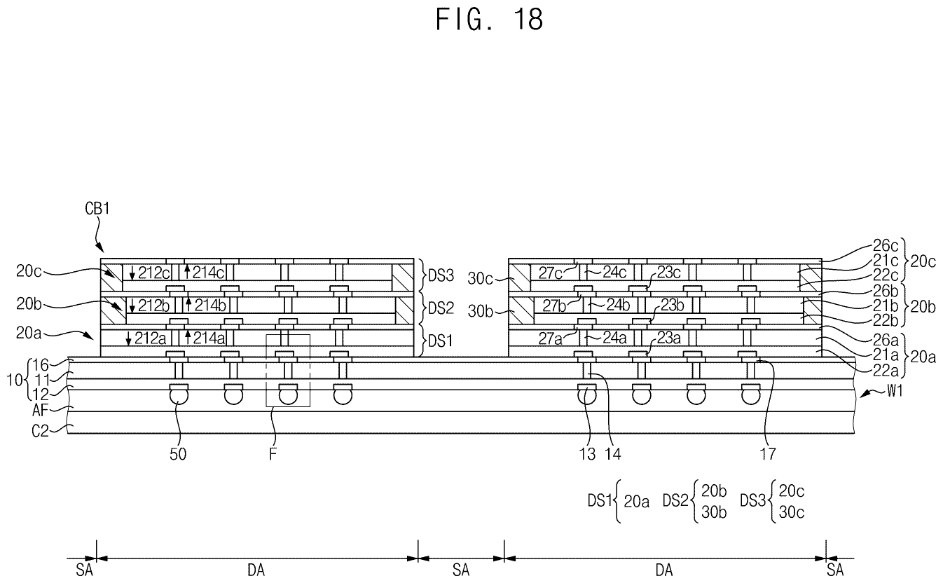

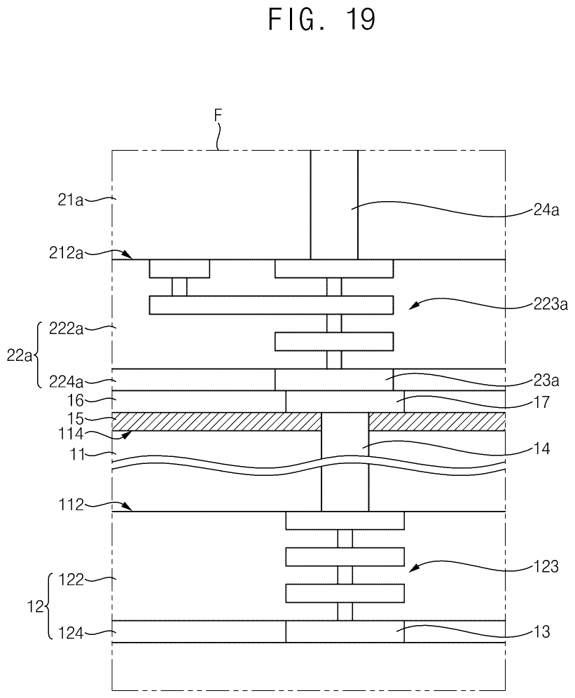

FIGS. 5 to 23 are views illustrating a method of manufacturing a semiconductor package in accordance with example embodiments. FIG. 6 is an enlarged cross-sectional view illustrating portion ‘C’ in FIG. 5. FIG. 9 is an enlarged cross-sectional view illustrating portion ‘D’ in FIG. 8. FIG. 11 is an enlarged cross-sectional view illustrating portion ‘E’ in FIG. 10. FIG. 19 is an enlarged cross-sectional view illustrating portion ‘F’ in FIG. 18.

Referring to FIGS. 5 to 12, first, first die structures may be formed on a first carrier substrate C1.

As illustrated in FIGS. 5 and 6, a plurality of first semiconductor chips (first core dies) 20a diced from a wafer may be placed on the first carrier substrate C1.

In example embodiments, the first carrier substrate C1 may include a wafer substrate as a base substrate on which a plurality of die structures are stacked at a wafer level. The first carrier substrate C1 may have a shape corresponding to a wafer on which the semiconductor process is performed. For example, the first carrier substrate may include a silicon substrate, a glass substrate, a non-metallic or metallic plate, etc.

The first carrier substrate C1 may include a die region DA where the die structure is disposed and a cutting region SA surrounding the die region DA. As will be described below, a gap filling layer covering or surrounding the core dies on the first carrier substrate C1 may be cut along the cutting region SA by a first sawing process to be individualized.

As illustrated in FIG. 5, the second wafer W2 may include a substrate 21a and a front insulating layer 22a having first bonding pads 23a that are provided in an outer surface thereof. Additionally, the second wafer W2 may include a plurality of through electrodes 24a that are provided in the substrate 21a and are electrically connected to the first bonding pads 23a.

The substrate 21a may have a first surface 212a and a second surface 214a opposite to each other. Circuit patterns may be provided on the first surface 212a of the substrate 21a. For example, the substrate 21a may include silicon, germanium, silicon-germanium, or III-V compounds, e.g., GaP, GaAs, GaSb, etc. In some embodiments, the substrate 21a may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the semiconductor chip may be a semiconductor device with a plurality of the circuit elements formed therein. The circuit patterns may be formed on the first surface 212a of the substrate 21a by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, etc. Examples of the non-volatile semiconductor memory devices may be EPROM, EEPROM, Flash EEPROM, etc.

As illustrated in FIG. 6, the front insulating layer 22a may be formed as an insulation interlayer on the first surface 212a of the substrate 21a, that is, the front surface. The front insulating layer 22a may include a plurality of insulating layers 222a and 224a and wirings 223a in the insulating layers. Additionally, the first bonding pad 23a may be provided in an outermost or lowermost insulating layer of the front insulating layer 22a.

For example, the front insulating layer 22a may include a metal wiring layer 222a and a first passivation layer 224a. The metal wiring layer 222a may include the plurality of wirings 223a therein. For example, the metal wiring layer 222a may include a metal wiring structure including the plurality of wirings 223a vertically stacked in buffer layers and insulating layers. The first bonding pad 23a may be formed on a lowermost wiring among the plurality of wirings 223a. For example, the wirings may include aluminum (Al), copper (Cu), tin (Sn), nickel (Ni), gold (Au), platinum (Pt), or alloys thereof.

The first passivation layer 224a may be formed on the metal wiring layer 222a and may expose at least a portion of the first bonding pad 23a. The first passivation layer 224a may include a plurality of stacked insulating layers. For example, the first passivation layer 224a may include a first protective layer including an oxide layer and a second protective layer including a nitride layer, sequentially stacked. The first protective layer may include silicon oxide, and the second protective layer may include silicon nitride or silicon carbonitride.

The first bonding pad 23a may be provided in the first passivation layer 224a. The first bonding pad 23a may be exposed through a side surface of the first passivation layer 224a. An upper surface of the first bonding pad 23a may be coplanar with an upper surface of the first passivation layer 224a and/or a lower surface of the first bonding pad 23a may be coplanar with a lower surface of the first passivation layer 224a. Although not illustrated in the figures, an insulation interlayer may be provided on the first surface 212a of the substrate 21a to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 23a by the lower wirings and the wirings.

The through electrode (e.g., through silicon via, TSV) 24a may vertically penetrate or extend through the insulation interlayer and extend from the first surface 212a of the substrate 21a to a predetermined depth. The through electrode 24a may contact an uppermost wiring of the metal wiring structure. Accordingly, the through electrode 24a may be electrically connected to the first bonding pad 23a by the wirings 223a.

A liner layer may be provided on a side surface of the through electrode 24a. The liner layer may include silicon oxide or carbon-doped silicon oxide. The liner layer may electrically insulate the through electrode 24a from the substrate 21a and the metal wiring layer 222a.

The through electrode 24a and the first bonding pad 23a may include a same metal. For example, the metal may include copper (Cu). However, it is not limited thereto, and the through electrode and the first bonding pad may include a material (e.g., gold (Au)) that can be bonded by inter-diffusion of metals by a high-temperature annealing process.

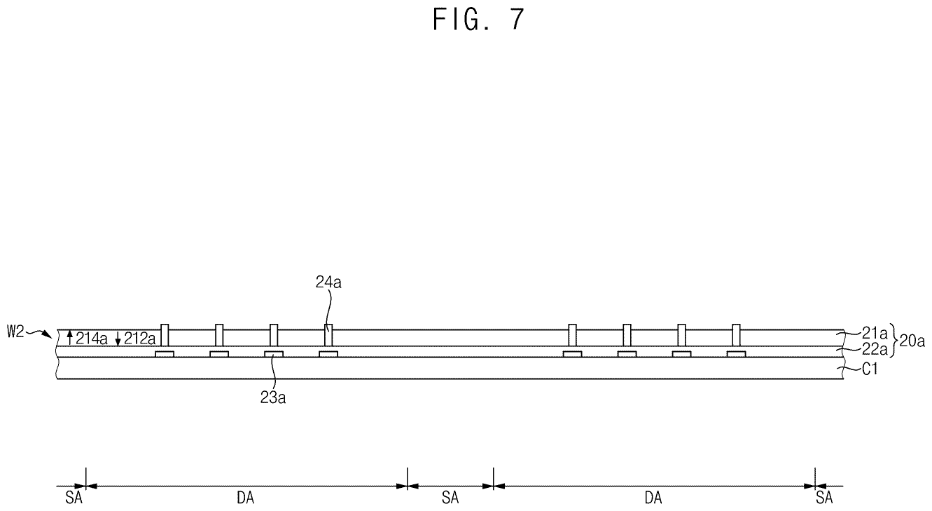

As illustrated in FIG. 7, the second surface 214a of the substrate 21a may be partially removed to expose one end portion of the through electrode 24a.

In example embodiments, first, a grinding process such as a back lap process may be performed to partially remove the second surface 214a of the substrate 21a, and then an etching process such as a silicon recess process may be performed to expose the end portion of the through electrode 24a. Accordingly, a thickness of the substrate 21a may be reduced to a desired thickness. For example, the substrate 21a may have the thickness in a range of about 10 μm to about 30 μm.

In the back lap process, the entire second surface 214a of the substrate 21a may be grinded. In the silicon recess process, only the silicon in the second surface 214a of the substrate 21a may be selectively etched. The etching process may be an isotropic dry etching process. The etching process may include a plasma etching process, etc. The plasma etching process may be performed using inductively coupled plasma, capacitively coupled plasma, microwave plasma, etc.

As illustrated in FIGS. 8 and 9, a backside insulating layer 26a having second bonding pads 27a in an outer surface thereof may be formed on the second surface 214a of the substrate 21a.

For example, a polishing stop layer may be formed on the second surface 214a of the substrate 21a, and a sacrificial layer may be formed on the polishing stop layer. The polishing stop layer may be conformally formed to cover end portions of the through electrodes 24a that protrude from the second surface 214a of the substrate 21a. For example, the polishing stop layer may have a thickness within a range of 0.1 μm to 1 μm. The polishing stop layer may include a material that can be used to detect a polishing end point in a subsequent chemical mechanical polishing process. The polishing stop layer may include a silicon nitride layer. The thickness and material of the polishing stop layer may be selected in consideration of a polishing selectivity and polishing conditions in the subsequent chemical mechanical polishing process.

The sacrificial layer may be formed to fill a gap between the protruding end portions of the through electrodes 24a. The sacrificial layer may include silicon oxide such as TEOS.

Then, a chemical mechanical polishing (CMP) process using the polishing stop layer to detect a polishing end point may be performed to remove the sacrificial layer to expose the end portions of the through electrodes 24a. Through the CMP process, the end portions of the through electrodes 24a and portions of the polishing stop layer covering or on them may be removed to form a polishing stop layer pattern 25a on the second surface 214a of the substrate 21a.

The polishing stop layer pattern 25a may expose end portions of the through electrodes 24a. The end portions of the through electrodes 24a may protrudes from the second surface 214a of the substrate 21a, and the polishing stop layer pattern 25a may cover or surround sidewalls of the end portions of the through electrodes 24a that protrude from the second surface 214a of the substrate 21a. Accordingly, upper surfaces of the through electrodes 24a may be exposed by the polishing stop layer pattern 25a. The upper surface of the polishing stop layer pattern 25a and the exposed upper surfaces of the through electrodes 24a may be coplanar or positioned on the same plane.

Then, the backside insulating layer 26a as a second passivation layer having the second bonding pad 27a that is electrically connected to the through electrode 24a may be formed on the polishing stop layer pattern 25a on the second surface 214a of the substrate 21a.

For example, after the backside insulating layer 26a is formed on the polishing stop layer pattern 25a on the second surface 214a of the substrate 21a, an opening may be formed in the backside insulating layer 26a to expose the through electrode 24a, and a plating process may be performed to form the second bonding pad 27a in the opening of the backside insulating layer 26a. The second bonding pad 27a may be disposed on the exposed upper surface of the through electrode 24a. An upper surface of the second bonding pad 27a may be coplanar with an upper surface of the backside insulating layer 26a and/or a lower surface of the second bonding pad 27a may be coplanar with a lower surface of the backside insulating layer 26a. The backside insulating layer 26a may include silicon oxide, carbon-doped silicon oxide, silicon carbonitride (SiCN), etc. Accordingly, the first and second bonding pads 23a and 27a may be electrically connected to each other by the through electrode 24a.

Thus, the plurality of first die structures each including a first core die 20a may be formed on the first carrier substrate C1. The first core dies 20a may be arranged on the first carrier substrate C1 such that the first surface 212a of the substrate 21a of each of the first core dies 20a faces the first carrier substrate C1. Each of the first core dies 20a may include the substrate 21a, the front insulating layer 22a, and the backside insulating layer 26a.

Referring to FIGS. 10 to 16, second die structures may be stacked respectively on the first die structures on the first carrier substrate C1.

As illustrated in FIGS. 10 and 11, a plurality of second core dies 20b may be attached on the first die structures on the first carrier substrate C1 (die-to-wafer hybrid bonding process).

In example embodiments, the second core dies 20b may be disposed on the first die structures respectively to correspond to the first core dies 20a of the first die structures. The second core dies 20b may be stacked such that a first surface 212b of a substrate 21b of each of the second core dies 20b faces the first carrier substrate C1.

A die bonding apparatus may pick up the second core die 20b individualized through a sawing process and may bond it to the first die structure. The die bonding apparatus may attach the second core die 20b to the first die structure by performing a thermal compression process at a predetermined temperature (for example, about 400° C. or less). By the thermal compression process, the second core die 20b and the first die structure may be bonded to each other through hybrid bonding. That is, a front surface of the second core die 20b, that is, a front insulating layer 22b on a first surface 212b of a substrate 21b may be directly bonded to the backside insulating layer 26a of the first die structure.

The second bonding pad 27a of the first die structure and a first bonding pad 23b of the second core die 20b may make contact with each other. When the first die structure and the second core die 20b are bonded to each other by die-to-wafer bonding, the second bonding pad 27a of the first die structure and the first bonding pads 23b of the second core die 20b may be bonded to each other by copper-copper hybrid bonding (Cu—Cu Hybrid Bonding).

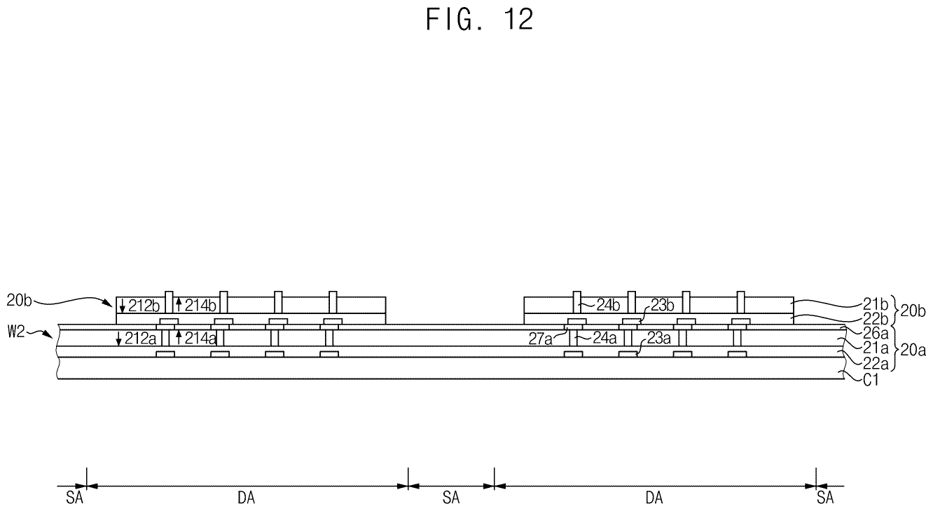

As illustrated in FIG. 12, the second surface 214b of the substrate 21b of the second core die 20b may be partially removed to expose one end portion of a through electrode 24b. First, a grinding process such as a back lap process may be performed to partially remove the second surface 214b of the substrate 21b, and then an etching process such as a silicon recess process may be performed to expose the end portion of the through electrode 24b. Accordingly, a thickness of the substrate 21b may be reduced to a desired thickness. For example, the substrate 21a may have the thickness in a range of about 10 μm to about 30 μm.

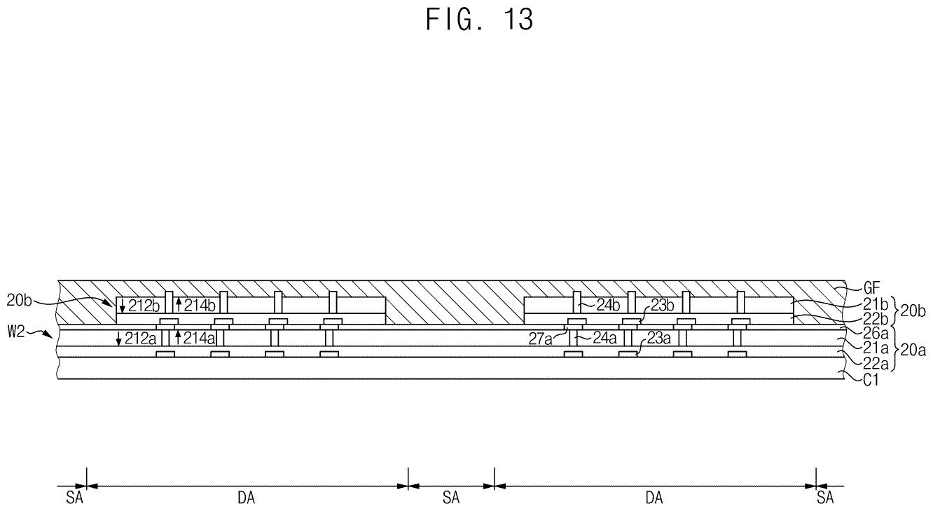

As illustrated in FIG. 13, a gap filling layer GF may be formed on the first die structure to cover the second core dies 20b.

For example, a polishing stop layer may be formed on the second wafer W2 along a profile of the second core dies 20b. The polishing stop layer may be conformally formed to cover end portions of the through electrodes 24b that protrude from the second surface 214b of the substrate 21b. For example, the polishing stop layer may have a thickness within a range of 0.1 μm to 1 μm. The polishing stop layer may include a material that can be used to detect a polishing end point in a subsequent chemical mechanical polishing process. The polishing stop layer may include a silicon nitride layer. The thickness and material of the polishing stop layer may be selected in consideration of a polishing selectivity and polishing conditions in the subsequent chemical mechanical polishing process.

Although it is not illustrated in the figures, a sacrificial layer may be formed on the polishing stop layer. The sacrificial layer may be formed to fill a gap between the protruding end portions of the through electrodes 24b. The sacrificial layer may include silicon oxide such as TEOS.

Then, a chemical mechanical polishing (CMP) process using the polishing stop layer to detect a polishing end point may be performed to remove the sacrificial layer to expose the end portions of the through electrodes 24a. Through the CMP process, the end portions of the through electrodes 24a and portions of the polishing stop layer covering them may be removed to form a polishing stop layer pattern 25a on the second surface 214a of the substrate 21a.

The polishing stop layer pattern 25a may expose end portions of the through electrodes 24a. The end portions of the through electrodes 24a may protrudes from the second surface 214a of the substrate 21a, and the polishing stop layer pattern 25a may cover sidewalls of the end portions of the through electrodes 24a that protrude from the second surface 214a of the substrate 21a. Accordingly, upper surfaces of the through electrodes 24a may be exposed by the polishing stop layer pattern 25a. The upper surface of the polishing stop layer pattern 25a and the exposed upper surfaces of the through electrodes 24a may be coplanar or positioned on the same plane.

Then, the gap filling layer GF may be formed on the second wafer W2 to cover the polishing stop layer on the second core dies 20b. The gap filling layer GF may cover or surround an outer side surface and upper surfaces of the second core dies 20b. For example, the gap filling layer GF may be formed by a conformal deposition process such as an atomic layer deposition (ALD) process or a chemical vapor deposition (CVD) process. The gap filling layer may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

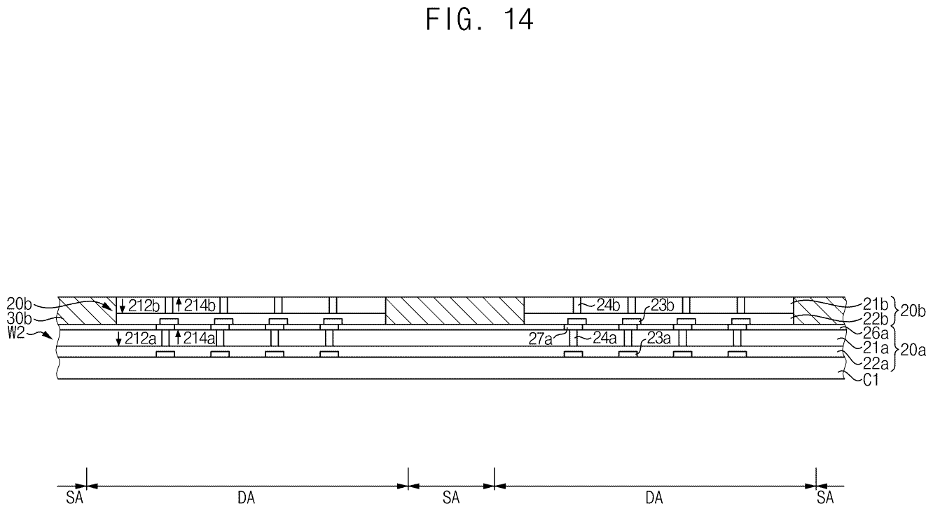

As illustrated in FIG. 14, an upper portion of the gap filling layer GF may be removed to form a gap filling portion or member 30b that covers or surrounds the outer side surface of the second core die 20b and exposes the upper surface of the second core die 20b. A chemical mechanical polishing (CMP) process using the polishing stop layer to detect a polishing end point may be performed to remove the upper portion of the gap filling layer GF and the sacrificial layer to expose end portions of the through electrodes 24b. Through the CMP process, the end portions of the through electrodes 24b and portions of the polishing stop layer covering them may be removed to form a polishing stop layer pattern on the second surface 214b of the substrate 21b.

The gap filling portion 30b may expose the polishing stop layer pattern and the end portions of the through electrodes 24b on the second surface 214b of the substrate 21b. The gap filling portion 30b may cover or surround outer side surfaces of the substrate 21b and the front insulating layer 22b.

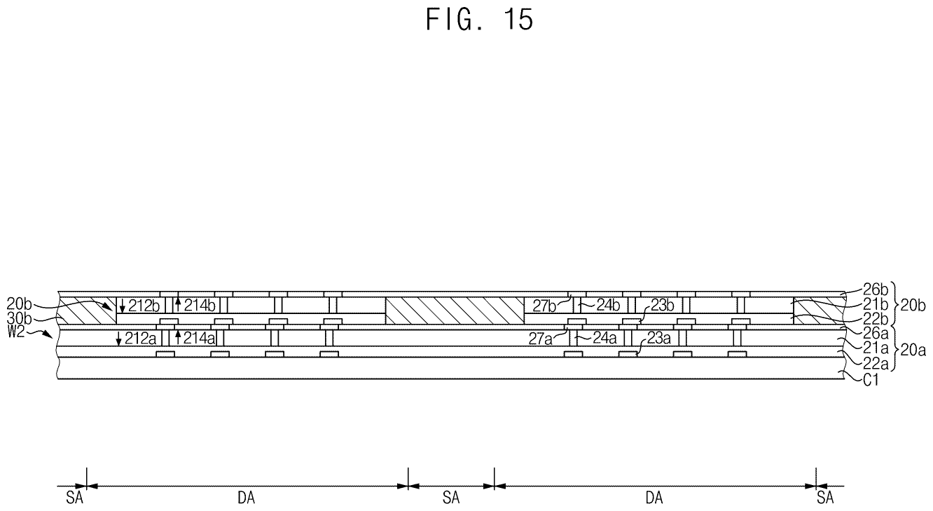

As illustrated in FIG. 15, a backside insulating layer 26b having second bonding pads 27b in an outer surface thereof may be formed on the second surface 214b of the substrate 21b.

In particular, the backside insulating layer 26b as a second passivation layer having the second bonding pad 27b that is electrically connected to the through electrode 24b may be formed on the polishing stop layer pattern 25b on the second surface 214b of the substrate 21b.

The polishing stop layer pattern may expose end portions of the through electrodes 24b. The end portions of the through electrodes 24b may protrude from the second surface 214b of the substrate 21b, and the polishing stop layer pattern 25b may cover or surround sidewalls of the end portions of the through electrodes 24b that protrude from the second surface 214b of the substrate 21b. Accordingly, upper surfaces of the through electrodes 24b may be exposed by the polishing stop layer pattern. An upper surface of the polishing stop layer pattern and the exposed upper surfaces of the through electrodes 24a may be coplanar or positioned on the same plane.

For example, after the backside insulating layer 26a is formed on the polishing stop layer pattern and the gap filling portion 30b on the second surface 214b of the substrate 21b, an opening may be formed in the backside insulating layer 26b to expose the through electrode 24b, and a plating process may be performed to form the second bonding pad 27b in the opening of the backside insulating layer 26b. The second bonding pad 27b may be disposed on the exposed upper surface of the through electrode 24b. The backside insulating layer 26b may include silicon oxide, carbon-doped silicon oxide, silicon carbonitride (SiCN), etc. Accordingly, the first and second bonding pads 23b and 27b may be electrically connected to each other by the through electrode 24b.

Thus, the second die structures each including a second core die 20b and the gap filling portion 30b covering or surrounding the outer side surface of the second core die 20b may be formed on the first die structures on the first carrier substrate C1. The second core dies 20b may be spaced apart from each other at the wafer level on the first die structures. The second core dies 20b may be arranged on the first die structures on the first carrier substrate C1 such that the first surface 212b of the substrate 21b of each of the second core dies 20b faces the first carrier substrate C1. Each of the second core dies 20b may include the substrate 21b, the front insulating layer 22b, and the backside insulating layer 26b. The gap filling portion 30b may cover the outer side surfaces of the substrate 21b and the front insulating layer 22b of the second core die 20b. The backside insulating layer 26b may extend laterally from or along the second surface 214b of the substrate 21b to cover an upper surface of the gap fill portion 30b.

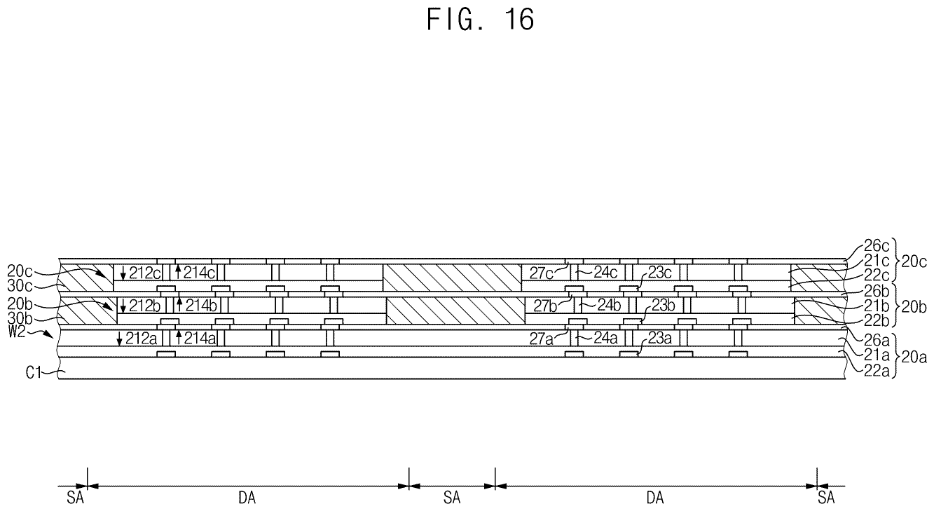

Referring to FIG. 16, processes the same as or similar to the processes described with reference to FIGS. 10 to 15 may be performed to form a third die structure on the second die structure.

The third die structure including a third core die 20c and a gap filling portion 30c covering or surrounding an outer side surface of the third core die 20c may be formed on the second die structure. The third core dies 20c may be spaced apart from each other at the wafer level on the second die structures. The third core dies 20c may be arranged on the second die structure such that a first surface 212c of a substrate 21c of the third core die 20c faces the first carrier substrate C1. Each of the third core dies 20c may include a substrate 21c, a front insulating layer 22c, and a backside insulating layer 26c. The gap filling portion 30c may cover or surround outer side surfaces of the substrate 21c and the front insulating layer 22c of the third core die 20c. The backside insulating layer 26c may extend laterally from or along a second surface 214c of the substrate 21c to cover an upper surface of the gap fill portion 30c.

The second bonding pad 27b of the second die structure and a first bonding pad 23c of the third core die 20c may make contact with each other. When the second die structure and the third core die 20c are bonded to each other by die-to-wafer bonding, the second bonding pad 27b of the second die structure and the first bonding pads 23c of the third core die 20c may be bonded to each other by copper-copper hybrid bonding (Cu—Cu Hybrid Bonding). A front surface of the third core die 20c, that is, the front insulating layer 22c on the first surface 212c of the substrate 21c may be directly bonded to the backside insulating layer 26b of the second die structure.

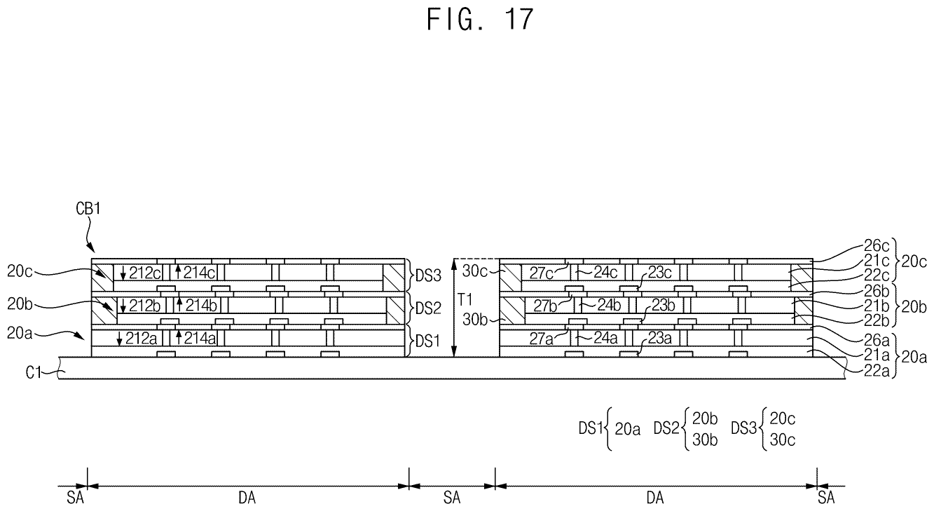

Referring to FIG. 17, the stacked first to third die structures may be cut along the cutting region SA, that is, a scribe lane region, by a first sawing process to form individual core die blocks CB1 on the first carrier substrate C1.

Each of the core die blocks CB1 may include first, second and third die structures DS1, DS2, and DS3 sequentially stacked. The first die structure DS1 may include the first core die 20a. The second die structure DS2 may include the second core die 20b and the gap filling portion 30b. The third die structure DS3 may include the third core die 20c and the gap filling portion 30c. In example embodiments, the core die block CB1 may include the core dies 20a, 20b, and 20c stacked in three stages, but it will be understood that the present inventive concept is not limited thereto.

The core die block CB1 may have a rectangular parallelepiped shape. A lower surface of the first die structure DS1 may serve as a lower surface of the core die block CB1, and an upper surface of the third die structure DS3 may serve as an upper surface of the core die block CB1.

The core die block CB1 may have a thickness T1 of at least 40 μm. Each of the first to third core dies 20a, 20b, and 20c may have a thickness within a range of about 10 μm to 30 μm. The first core die 20a may have a first planar area, and the second and third core dies 20b and 20c may have a second planar area that is less or smaller than the first planar area. The first core die 20a may have a first (horizontal) width, and the second and third core dies 20b and 20c may have a second (horizontal) width less than the first width.

Since the core die block CB1 is formed by cutting the stacked first, second and third die structures through the first sawing process, outer side surfaces of the first, second, and third die structures, that is, outer side surface of the gap filling portions 30b and 30c, of the core die block CB1 may be coplanar or positioned on the same plane.

Referring to FIGS. 18 and 19, the first core die blocks CB1 may be attached in a first stage on a first wafer W1 including buffer dies (die-to-wafer hybrid bonding process).

In example embodiments, first, conductive bumps 50 may be formed on a front surface of the first wafer W1 and an adhesive film AF may be formed on the front surface of the first wafer W1 to cover the conductive bumps 50. Then, the first wafer W1 may be attached to a second carrier substrate C2 using the adhesive film AF.

Then, the first core die blocks CB1 may be disposed on the first wafer W1 to correspond to die regions DA. The first core die blocks CB1 may be stacked such that the lower surface of the first core die block CB1, that is, the lower surface of the first die structure DS1 faces the first wafer W1.

A die bonding apparatus may pick up the first core die block CB1 individualized through the first sawing process and may bond it to the first wafer W1. The die bonding apparatus may attach the first core die block CB1 to the first wafer W1 by performing a thermal compression process at a predetermined temperature (for example, about 400° C. or less). By the thermal compression process, the first core die block CB1 and the first wafer W1 may be bonded to each other through hybrid bonding. That is, the lower surface of the first core die block CB1, that is, the front insulating layer 22a of the first die structure DS1 may be directly bonded to a backside insulating layer 16 of a substrate 11 of the first wafer W1.

A second bonding pad 17 of the first wafer W1 and the first bonding pad 23a of the first die structure DS1 of the first core die block CB1 may make contact with each other. The lower surface of the first core die block CB1, that is the front surface of the first core die 20a of the first die structure DS1 and a backside surface of the first wafer W1 may be bonded to face each other. When the first wafer W1 and the first core die block CB1 are bonded to each other by die-to-wafer bonding, the second bonding pad 17 of the first wafer and the first bonding pads 23a of the first core die 20a may be bonded to each other by copper-copper hybrid bonding (Cu—Cu Hybrid Bonding).

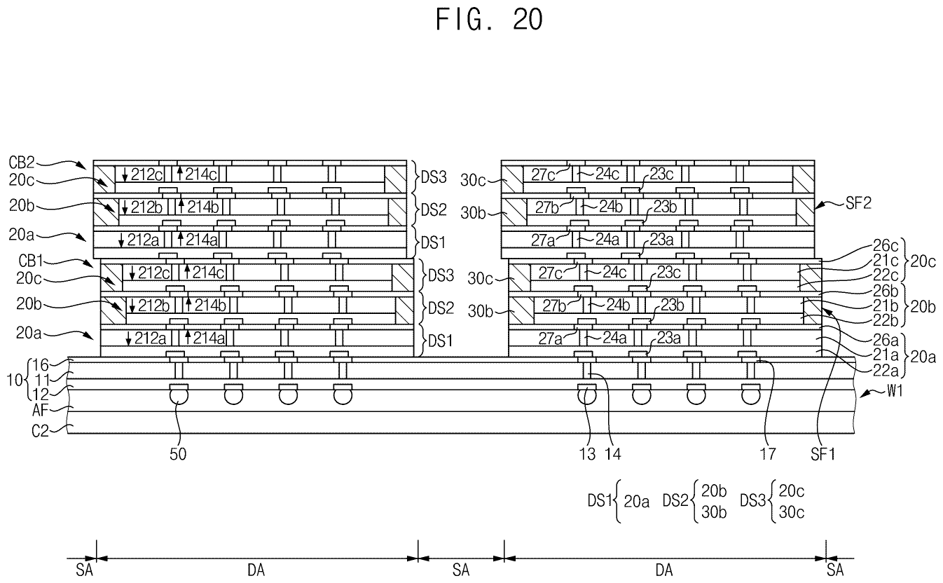

Referring to FIG. 20, processes the same as or similar to the processes described with reference to FIGS. 18 and 19 may be performed to attach a plurality of second core die blocks CB2 in a second stage on the first core die blocks CB1 on the first wafer W1 (die-to-wafer hybrid bonding process).

A lower surface of the second core die block CB2 of the second stage may be stacked to face the upper surface of the first core die block CB1 of the first stage. Through a thermal compression process, the second core die block CB2 of the second stage and the first core die block CB1 of the first stage may be bonded to each other through hybrid bonding. That is, a front insulating layer 22a of a first core die 20a of the second core die block CB2 may be directly bonded to the backside insulating layer 26c of the third core die 20c of the first core die block CB1 of the first stage. When the first core die block CB1 of the first stage and the second core die block CB2 of the second stage are bonded to each other by die-to-die bonding, the second bonding pad 27c of the third core die 20c of the first core die block CB1 of the first stage and a first bonding pad 23a of the first core die 20a of the second core die block CB2 of the second stage may be bonded to each other by copper-copper hybrid bonding (Cu—Cu Hybrid Bonding).

Since the first core die block CB1 and the second core die block CB2 are bonded to each other by die-to-die bonding, misalignment between the first core die block CB1 and the second core die block CB2 may occur. Accordingly, an outer side surface SF1 of the first core die block CB1 and an outer side surface SF2 of the second core die block CB2 may be positioned on different planes respectively.

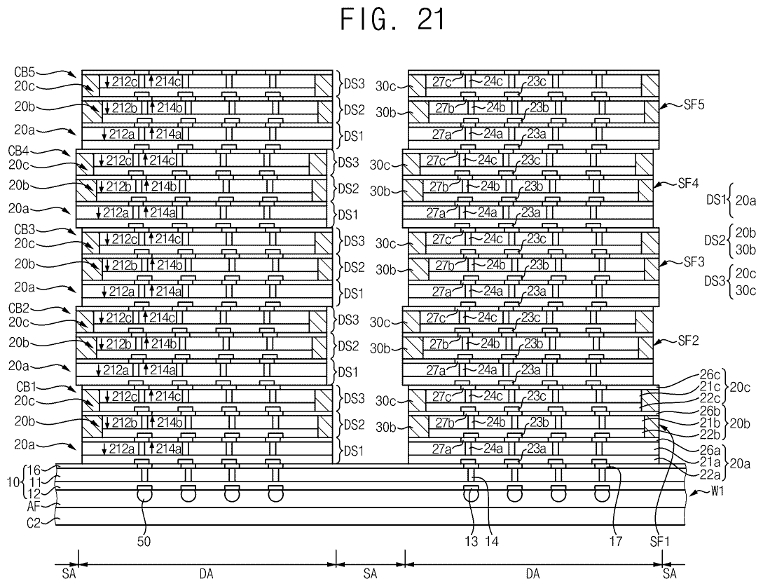

Referring to FIG. 21, processes the same as or similar to the processes described with reference to FIG. 20 may be performed to attach a plurality of third core die blocks CB3 in a third stage on the second core die blocks CB2 (die-to-wafer hybrid bonding process), to attach a plurality of fourth core die blocks CB4 in a fourth stage on the third core die blocks CB3 (die-to-wafer hybrid bonding process), and to attach a plurality of fifth core die blocks CB5 in a fifth stage on the fourth core die blocks CB4 (die-to-wafer hybrid bonding process).

A lower surface of the third core die block CB3 of the third stage may be stacked to face an upper surface of the second core die block CB2 of the second stage. Through a thermal compression process, the third core die block CB3 of the third stage and the second core die block CB2 of the second stage may be bonded to each other through hybrid bonding. That is, a front insulating layer 22a of a first core die 20a of the third core die block CB3 may be directly bonded to a backside insulating layer 26c of a third core die 20c of the second core die block CB2 of the second stage. When the second core die block CB2 of the second stage and the third core die block CB3 of the third stage are bonded to each other by die-to-die bonding, a second bonding pad 27c of the third core die 20c of the second core die block CB2 of the second stage and a first bonding pad 23a of the first core die 20a of the third core die block CB3 of the third stage may be bonded to each other by copper-copper hybrid bonding (Cu—Cu Hybrid Bonding).

Since the second core die block CB2 and the third core die block CB3 are bonded to each other by die-to-die bonding, misalignment between the second core die block CB2 and the third core die block CB3 may occur. Accordingly, the outer side surface SF2 of the second core die block CB2 and an outer side surface SF3 of the third core die block CB3 may be positioned on different planes respectively.

Then, a lower surface of the fourth core die block CB4 of the fourth stage may be stacked to face an upper surface of the third core die block CB3 of the third stage. Through a thermal compression process, the fourth core die block CB4 of the fourth stage and the third core die block CB3 of the third stage may be bonded to each other through hybrid bonding. That is, a front insulating layer 22a of a first core die 20a of the fourth core die block CB4 may be directly bonded to a backside insulating layer 26c of a third core die 20c of the third core die block CB3 of the third stage. When the third core die block CB3 of the third stage and the fourth core die block CB4 of the fourth stage are bonded to each other by die-to-die bonding, a second bonding pad 27c of the third core die 20c of the third core die block CB3 of the third stage and a first bonding pad 23a of the first core die 20a of the fourth core die block CB4 of the fourth stage may be bonded to each other by copper-copper hybrid bonding (Cu—Cu Hybrid Bonding).

Since the third core die block CB3 and the fourth core die block CB4 are bonded to each other by die-to-die bonding, misalignment between the third core die block CB3 and the fourth core die block CB4 may occur. Accordingly, the side surface SF3 of the third core die block CB3 and a side surface SF4 of the fourth core die block CB4 may be positioned on different planes respectively.

Then, a lower surface of the fifth core die block CB5 of the fifth stage may be stacked to face an upper surface of the fourth core die block CB4 of the fourth stage. Through a thermal compression process, the fifth core die block CB5 of the fifth stage and the fourth core die block CB4 of the fourth stage may be bonded to each other through hybrid bonding. That is, a front insulating layer 22a of a first core die 20a of the fifth core die block CB5 may be directly bonded to a backside insulating layer 26c of a third core die 20c of the fourth core die block CB4 of the fourth stage. When the fourth core die block CB4 of the fourth stage and the fifth core die block CB5 of the fifth stage are bonded to each other by die-to-die bonding, a second bonding pad 27c of the third core die 20c of the fourth core die block CB4 of the fourth stage and a first bonding pad 23a of the first core die 20a of the fifth core die block CB5 of the fifth stage may be bonded to each other by copper-copper hybrid bonding (Cu—Cu Hybrid Bonding).

Since the fourth core die block CB4 and the fifth core die block CB5 are bonded to each other by die-to-die bonding, misalignment between the fourth core die block CB4 and the fifth core die block CB5 may occur. Accordingly, the outer side surface SF4 of the fourth core die block CB4 and an outer side surface SF5 of the fifth core die block CB5 may be positioned on different planes respectively.

The number of the core die blocks sequentially stacked on the first wafer W1 may be determined according to the total number of core dies stacked on the buffer die and the number of the core dies in each core die block.

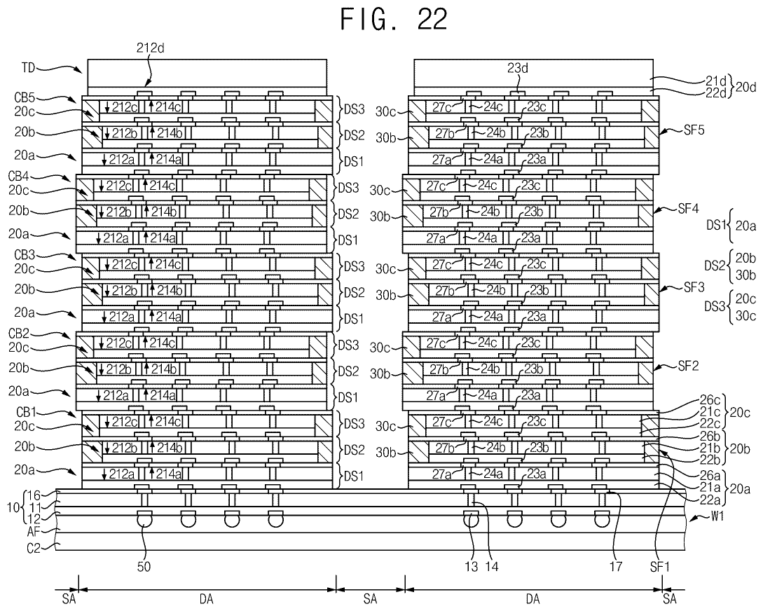

Referring to FIG. 22, a top core die stack TD may be attached to the fifth core die block CB5.

In example embodiments, the top core die stack TD may include a top core die 20d. The top core dies 20d may be disposed on the fifth core die blocks CB5 to correspond to the first core dies 20c of the fifth core die blocks CB5. A first surface 212d of a substrate 21d of the top core die 20d may be stacked to face the fifth core die block CB5.

A die bonding apparatus may pick up the top core die 20d individualized through a sawing process and may bond it to the fifth core die block. The die bonding apparatus may attach the top core die 20d to the fifth core die block by performing a thermal compression process at a predetermined temperature (for example, about 400° C. or less). By the thermal compression process, the top core die 20d and the fifth core die block may be bonded to each other through hybrid bonding. That is, a front surface of the top core die 20d, that is, a front insulating layer 22d on the first surface 212d of the substrate 21d may be directly bonded to a backside insulating layer 26c of the third core die 20c of the fifth core die block.

A second bonding pad 27c of the third core die 20c of the fifth core die block and a first bonding pad 23d of the top core die 20d may make contact with each other. When the fifth core die block and the top core die 20d are bonded to each other by die-to-wafer bonding, the second bonding pad 27c of the third core die 20c of the fifth core die block and the first bonding pads 23d of the top core die 20d may be bonded to each other by copper-copper hybrid bonding (Cu—Cu Hybrid Bonding).

A thickness of the top core die 20d may be greater than thicknesses of the middle core dies 20a, 20b, and 20c. The thickness of the top core die 20d may be within a range of 50 μm to 300 μm.

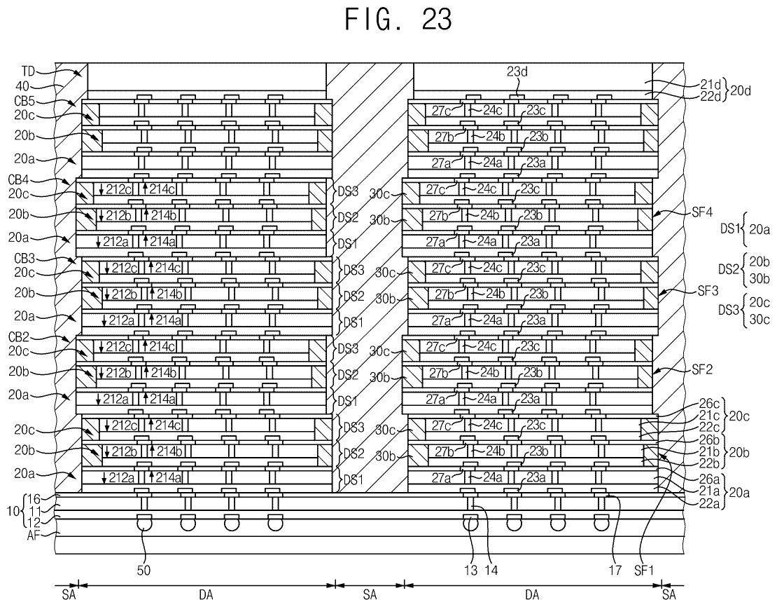

Referring to FIG. 23, a molding member 40 may be formed to fill or be in gaps between the first, second, third, fourth and fifth core die blocks CB1, CB2, CB3, CB4 and CB5 sequentially stacked on the first wafer W1.

For example, the molding member 40 as a gap filling portion may be formed on the first wafer W1 to fill the gap between the first, second, and third core die blocks CB1, CB2, and CB3. The molding member 40 may expose an upper surface of the top core die 20d. An upper surface of the molding member 40 and an upper surface of the top core die 20d may be coplanar. The molding member 40 may directly contact the outer side surfaces SF1, SF2, SF3, SF4 and SF5 of the first, second, third, fourth and fifth core die blocks CB1, CB2, CB3, CB4 and CB5.

For example, the molding member may include a thermosetting resin. The molding material may include an epoxy mold compound (EMC). The molding material may include UV resin, polyurethane resin, silicone resin, silica filler, etc.

Then, portions of the first wafer W1 and the molding member 40 may be cut along a cutting region SA, that is, a scribe lane region by a second sawing process to complete the semiconductor package 100 of FIG. 1.

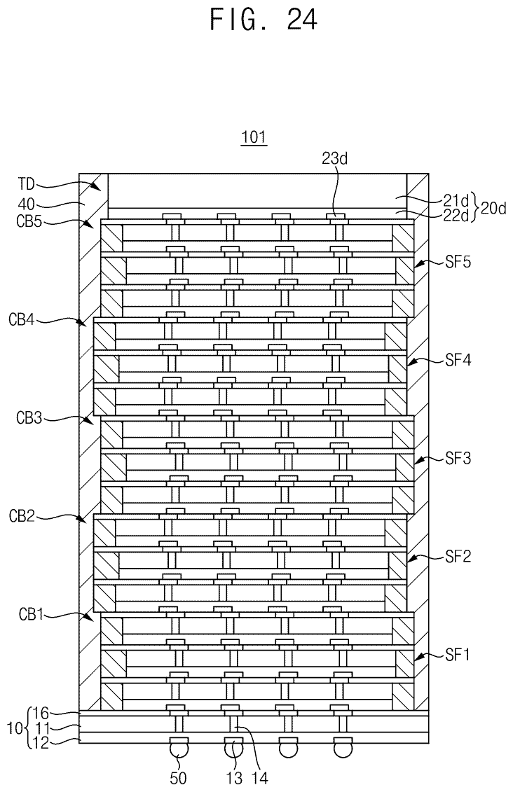

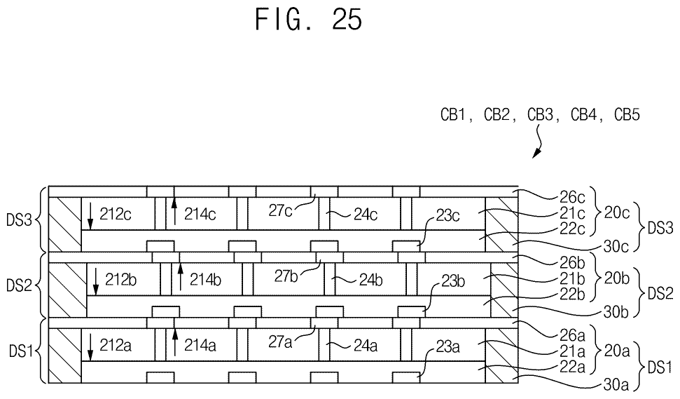

FIG. 24 is a cross-sectional view illustrating a semiconductor package in accordance with example embodiments. FIG. 25 is a cross-sectional view illustrating a core die block of the semiconductor package in FIG. 24. The semiconductor package is substantially the same as or similar to the semiconductor package described with reference to FIG. 1 except for a configuration of a core die block. Thus, same reference numerals will be used to refer to the same or like elements and any further repetitive explanation concerning the above elements may be omitted in the interest of brevity.

Referring to FIGS. 24 and 25, a semiconductor package 101 may include a buffer die 10, and a plurality of core die blocks CB1, CB2, CB3, CB4, CB5 sequentially stacked on the buffer die 10. Each of the core die blocks CB1, CB2, CB3, CB4, CB5 may include first, second and third die structures DS1, DS2 and DS3 sequentially stacked. Each of the core die blocks CB1, CB2, CB3, CB4, CB5 may include a plurality of core dies 20a, 20b, and 20c sequentially stacked, and a plurality of gap filling portions or members 30a, 30b, and 30c respectively covering or surrounding outer side surfaces of the plurality of core dies 20a, 20b, and 20c stacked in at least two stages.

In example embodiments, the gap filling portion 30a of the first die structure DS1 may at least partially cover or surround the outer side surface of the first core die 20a. The gap filling portion 30a may cover or surround outer side surfaces of a substrate 21a and a front insulating layer 22a of the first core die 20a. A backside insulating layer 26a of the first core die 20a may cover an upper surface of the gap filling portion 30a. The backside insulating layer 26a may protrude or extend in a horizontal direction from the outer side surfaces of the substrate 21a and the front insulating layer 22a, and the protruding portion of the backside insulating layer 26a may cover the upper surface of the gap filling portion 30a. An outer side surface of the backside insulating layer 26b and an outer side surface of the gap filling portion 30a may be coplanar or positioned on the same plane.

Similarly, the gap filling portion 30b of the second die structure DS2 may at least partially cover or surround the outer side surface of the second core die 20b. The gap filling portion 30b may cover or surround outer side surfaces of a substrate 21b and a front insulating layer 22b of the second core die 20b. A backside insulating layer 26b of the second core die 20b may cover an upper surface of the gap filling portion 30b. The backside insulating layer 26b may protrude or extend in a horizontal direction from the outer side surfaces of the substrate 21b and the front insulating layer 22b, and the protruding portion of the backside insulating layer 26b may cover the upper surface of the gap filling portion 30b. An outer side surface of the backside insulating layer 26b and an outer side surface of the gap filling portion 30b may be coplanar or positioned on the same plane.

Similarly, the gap filling portion 30c of the third die structure DS3 may at least partially cover or surround the outer side surface of the third core die 20c. The gap filling portion 30c may cover or surround outer side surfaces of a substrate 21c and a front insulating layer 22c of the third core die 20c. A backside insulating layer 26c of the third core die 20c may cover an upper surface of the gap filling portion 30c. The backside insulating layer 26c may protrude or extend in a horizontal direction from the outer side surfaces of the substrate 21c and the front insulating layer 22c, and the protruding portion of the backside insulating layer 26c may cover the upper surface of the gap filling portion 30c. An outer side surface of the backside insulating layer 26c and the outer side surface of the gap filling portion 30c may be coplanar or positioned on the same plane.

The backside insulating layer 26a of the first die structure DS1 may cover or be on a lower surface of the gap filling portion 30b of the second die structure DS2. The backside insulating layer 26b of the second die structure DS2 may cover or be on a lower surface of the gap filling portion 30c of the third die structure RD3. Additionally, the outer side surfaces of the gap filling portions 30a, 30b, 30c of the first core die block CB1 may be coplanar or positioned on the same plane.

Hereinafter, a method of manufacturing the semiconductor package of FIGS. 24 and 25 will be described.

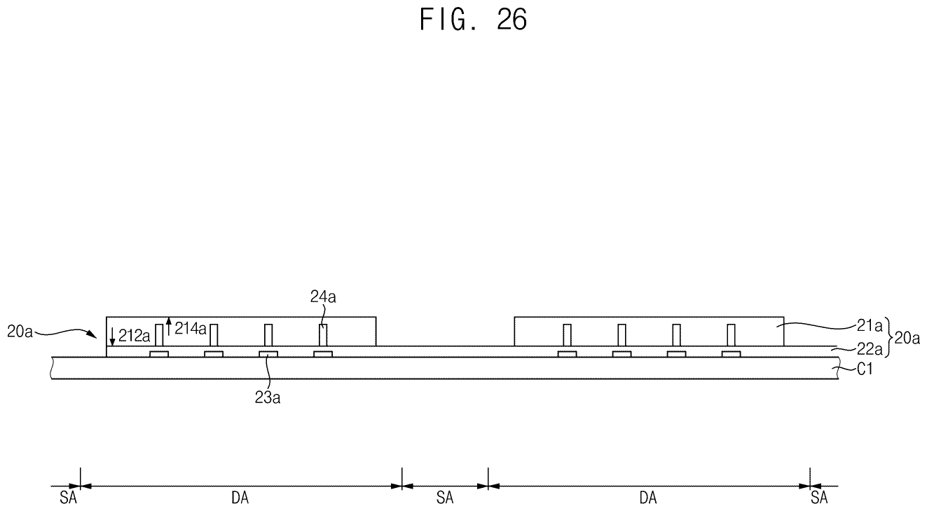

FIGS. 26 to 34 are views illustrating a method of manufacturing a semiconductor package in accordance with example embodiments.

Referring to FIGS. 26 to 30, first die structures may be formed on a first carrier substrate C1.

As illustrated in FIG. 26, a plurality of first semiconductor chips (first core dies) 20a diced from a wafer may be placed on the first carrier substrate C1.

The first core die 20a may include a substrate 21a and a front insulating layer 22a having first bonding pads 23a that are provided in an outer surface thereof. Additionally, the first core die 20a may include a plurality of through electrodes 24a that are provided in the substrate 21a and are electrically connected to the first bonding pads 23a.

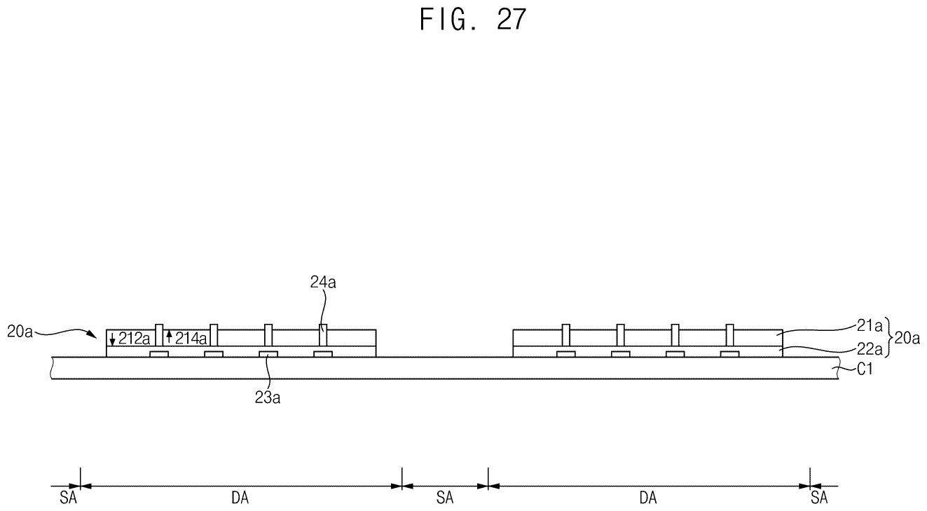

As illustrated in FIG. 27, a second surface 214a of the substrate 21a may be partially removed to expose one end portion of the through electrode 24a.

In example embodiments, first, a grinding process such as a back lap process may be performed to partially remove the second surface 214a of the substrate 21a, and then an etching process such as a silicon recess process may be performed to expose the end portion of the through electrode 24a. Accordingly, a thickness of the substrate 21a may be reduced to a desired thickness. For example, the substrate 21a may have the thickness in a range of about 10 μm to about 30 μm.

In the back lap process, the entire second surface 214a of the substrate 21a may be grinded. In the silicon recess process, only the silicon in the second surface 214a of the substrate 21a may be selectively etched. The etching process may be an isotropic dry etching process. The etching process may include a plasma etching process, etc. The plasma etching process may be performed using inductively coupled plasma, capacitively coupled plasma, microwave plasma, etc.

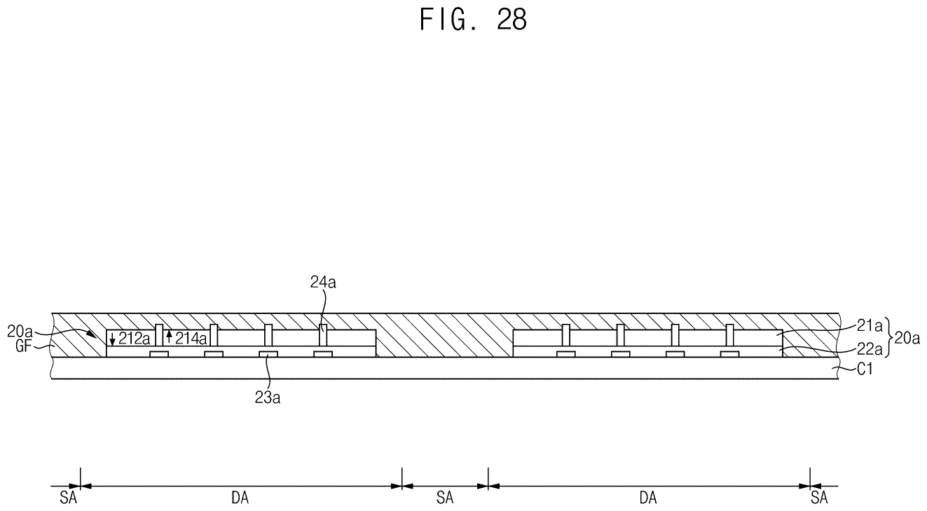

As illustrated in FIG. 28, a gap filling layer GF may be formed on the first carrier substrate C1 to cover the first core dies 20a.

First, a polishing stop layer may be formed along a profile of the first core dies 20a on the first carrier substrate C1. The polishing stop layer may be conformally formed to cover the end portions of the through electrodes 24a that protrude from the second surface 214a of the substrate 21a. Although it is not illustrated in the figures, a sacrificial layer may be formed on the polishing stop layer. The sacrificial layer may be formed to fill a gap between the protruding end portions of the through electrodes 24a.

Then, the gap filling layer GF may be formed to cover the polishing stop layer on the first core dies 20 on the first carrier substrate C1. The gap filling layer GF may cover or surround side surfaces and upper surfaces of the first core dies 20a. For example, the gap filling layer GF may be formed by a conformal deposition process such as an atomic layer deposition (ALD) process or a chemical vapor deposition (CVD) process. The gap filling layer may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

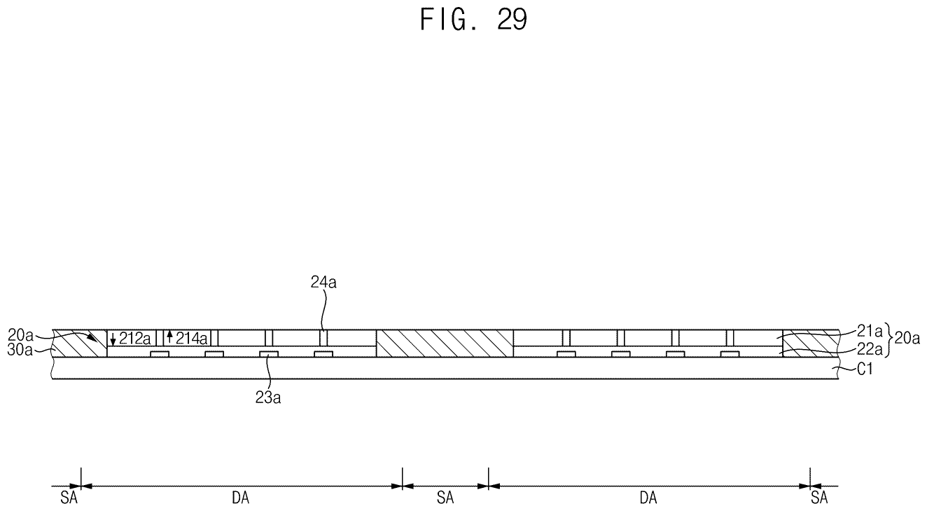

As illustrated in FIG. 29, an upper portion of the gap filling layer GF may be removed to form a gap filling portion 30a that covers or surrounds an outer side surface of the first core die 20a and exposes an upper surface of the first core die 20a. A chemical mechanical polishing (CMP) process using the polishing stop layer to detect a polishing end point may be performed to remove the upper portion of the gap filling layer GF and the sacrificial layer to expose the end portions of the through electrodes 24a. Through the CMP process, the end portions of the through electrodes 24a and portions of the polishing stop layer covering them may be removed to form a polishing stop layer pattern on the second surface 214a of the substrate 21a.

The gap filling portion 30a may expose the polishing stop layer pattern and end portions of the through electrodes 24a on the second surface 214a of the substrate 21a. The gap filling portion 30a may cover or surround outer side surfaces of the substrate 21a and the front insulating layer 22a.

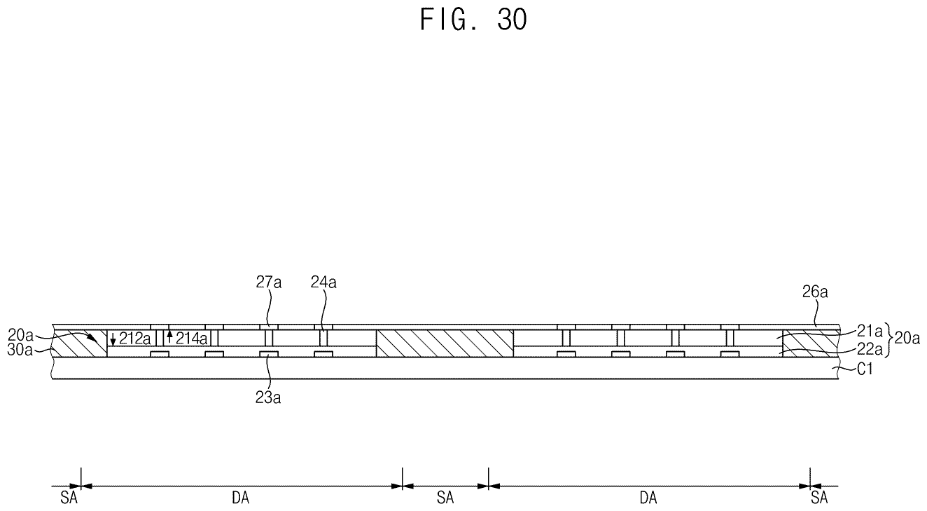

As illustrated in FIG. 30, a backside insulating layer 26a having a second bonding pad 27a in an outer surface thereof may be formed on the second surface 214a of the substrate 21a.

In particular, the backside insulating layer 26a as a second passivation layer having the second bonding pad 27a that is electrically connected to the through electrode 24a may be formed on the etch stop layer pattern 25a on the second surface 214a of the substrate 21a.

The polishing stop layer pattern may expose the end portions of the through electrodes 24a. The end portions of the through electrodes 24a may protrude from the second surface 214a of the substrate 21a, and the polishing stop layer pattern may cover or surround sidewalls of the end portions of the through electrodes 24a that protrude from the second surface 214a of the substrate 21a. Accordingly, the upper surfaces of the through electrodes 24a may be exposed by the polishing stop layer pattern. An upper surface of the polishing stop layer pattern and the exposed upper surfaces of the through electrodes 24a may be coplanar or positioned on the same plane.

For example, after the backside insulating layer 26a is formed on the polishing stop layer pattern and the gap filling portion 30a on the second surface 214a of the substrate 21a, an opening may be formed in the backside insulating layer 26a to expose the through electrode 24a, and a plating process may be performed to form the second bonding pad 27a in the opening of the backside insulating layer 26a. The second bonding pad 27a may be disposed on the exposed surface of the through electrode 24a. The backside insulating layer 26a may include silicon oxide, carbon-doped silicon oxide, silicon carbonitride (SiCN), etc. Accordingly, the first and second bonding pads 23a and 27a may be electrically connected to each other by the through electrode 24a.

Thus, the first die structure including the first core die 20a and the gap filling portion 30a covering or surrounding the outer side surface of the first core die 20a may be formed on the first carrier substrate C1. The first core dies 20a may be spaced apart from each other at the wafer level on the first carrier substrate C1. The first core dies 20a may be arranged on the first carrier substrate C1 such that the first surface 212a of the substrate 21a of the first core die 20a faces the first carrier substrate C1. Each of the first core dies 20a may include the substrate 21a, the front insulating layer 22a, and the backside insulating layer 26a. The gap filling portion 30a may cover or surround the outer side surfaces of the substrate 21a and the front insulating layer 22a of the first core die 20a. The backside insulating layer 26a may extend laterally from or along the second surface 214a of the substrate 21a to cover an upper surface of the gap fill portion 30a.

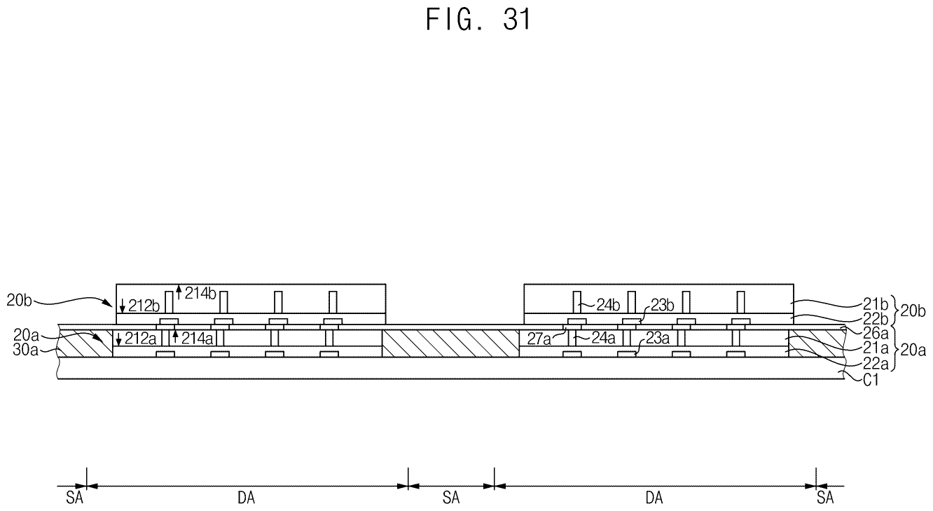

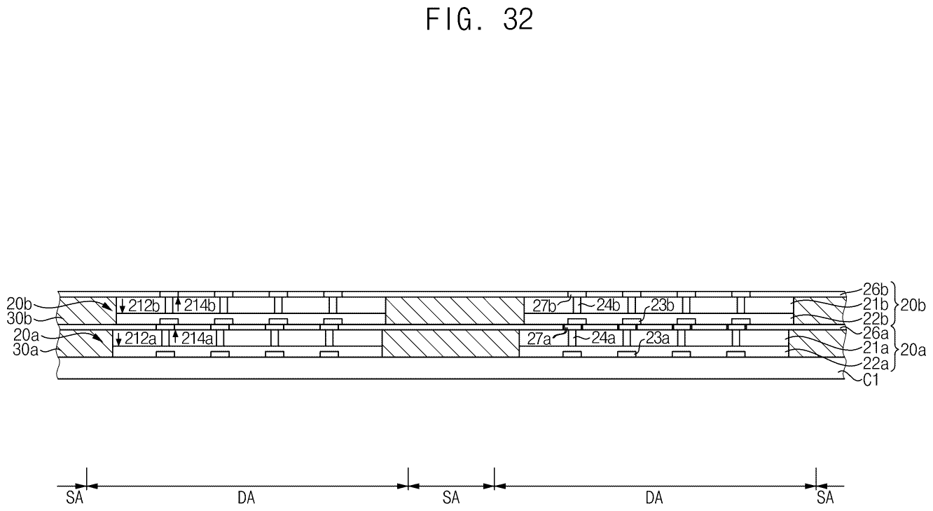

Referring to FIGS. 31 and 32, processes the same as or similar to the processes described with reference to FIGS. 27 to 30 may be performed to stack a second die structure on the first die structure on the first carrier substrate C1.

As illustrated in FIG. 31, a plurality of second core dies 20b may be attached on the first die structures on the first carrier substrate C1 (die-to-wafer hybrid bonding process).

In example embodiments, the second core dies 20b may be disposed on the first die structures respectively to correspond to the first core dies 20a of the first die structures. The second core dies 20b may be stacked such that a first surface 212b of a substrate 21b of each of the second core dies 20b faces the first carrier substrate C1.

A die bonding apparatus may pick up the second core die 20b individualized through a sawing process and may bond it to the first die structure. The die bonding apparatus may attach the second core die 20b to the first die structure by performing a thermal compression process at a predetermined temperature (for example, about 400° C. or less). By the thermal compression process, the second core die 20b and the first die structure may be bonded to each other through hybrid bonding. That is, a front surface of the second core die 20b, that is, a front insulating layer 22b on a first surface 212b of a substrate 21b may be directly bonded to the backside insulating layer 26a of the first die structure.

The second bonding pad 27a of the first die structure and a first bonding pad 23b of the second core die 20b may make contact with each other. When the first die structure and the second core die 20b are bonded to each other by die-to-wafer bonding, the second bonding pad 27a of the first die structure and the first bonding pad 23b of the second core die 20b may be bonded to each other by copper-copper hybrid bonding (Cu—Cu Hybrid Bonding).

As illustrated in FIG. 32, the second surface 214b of the substrate 21b of the second core die 20b may be partially removed to expose one end portion of a through electrode 24b. Then, a gap filling layer may be formed on the first die structure to cover the second core dies 20b, and an upper portion of the gap filling layer may be removed to form a gap filling portion 30b that covers or surrounds an outer side surface of the second core die 20b and exposes an upper surface of the second core die 20b. Then, a backside insulating layer 26b having second bonding pads 27b in an outer surface thereof may be formed on the second surface 214b of the substrate 21b.

Thus, the second die structures each including a second core die 20b and the gap filling portion 30b covering or surrounding the outer side surface of the second core die 20b may be formed on the first die structures on the first carrier substrate C1. The second core dies 20b may be spaced apart from each other at the wafer level on the first die structures. The second core dies 20b may be arranged on the first die structures on the first carrier substrate C1 such that the first surface 212b of the substrate 21b of each of the second core dies 20b faces the first carrier substrate C1. Each of the second core dies 20b may include the substrate 21b, the front insulating layer 22b, and the backside insulating layer 26b. The gap filling portion 30b may cover or surround the outer side surfaces of the substrate 21b and the front insulating layer 22b of the second core die 20b. The backside insulating layer 26b may extend laterally from or along the second surface 214b of the substrate 21b to cover an upper surface of the gap fill portion 30b.

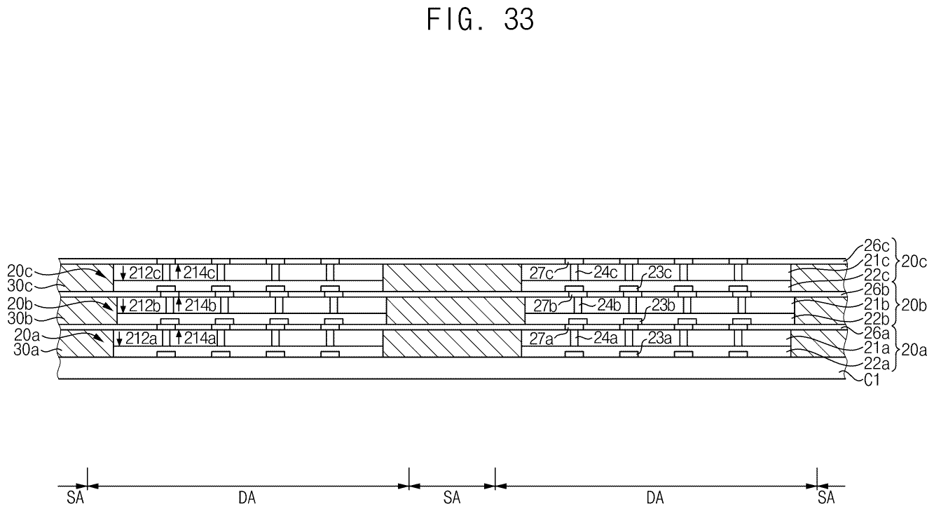

Referring to FIG. 33, processes the same as or similar to the processes described with reference to FIGS. 31 and 32 may be performed to stack a third die structure on a second die structure on the first carrier substrate C1.

The third die structure including a third core die 20c and a gap filling portion 30c covering or surrounding an outer side surface of the third core die 20c may be formed on the second die structure. The third core dies 20c may be spaced apart from each other at the wafer level on the second die structures. The third core dies 20c may be arranged on the second die structure such that a first surface 212c of a substrate 21c of the third core die 20c faces the first carrier substrate C1. Each of the third core dies 20c may include a substrate 21c, a front insulating layer 22c, and a backside insulating layer 26c. The gap filling portion 30c may cover or surround outer side surfaces of the substrate 21c and the front insulating layer 22c of the third core die 20c. The backside insulating layer 26c may extend laterally from or along a second surface 214c of the substrate 21c to cover an upper surface of the gap fill portion 30c.

The second bonding pad 27b of the second die structure and a first bonding pad 23c of the third core die 20c may make contact with each other. When the second die structure and the third core die 20c are bonded to each other by die-to-wafer bonding, the second bonding pad 27b of the second die structure and the first bonding pads 23c of the third core die 20c may be bonded to each other by copper-copper hybrid bonding (Cu—Cu Hybrid Bonding). A front surface of the third core die 20c, that is, the front insulating layer 22c on the first surface 212c of the substrate 21c may be directly bonded to the backside insulating layer 26b of the second die structure.

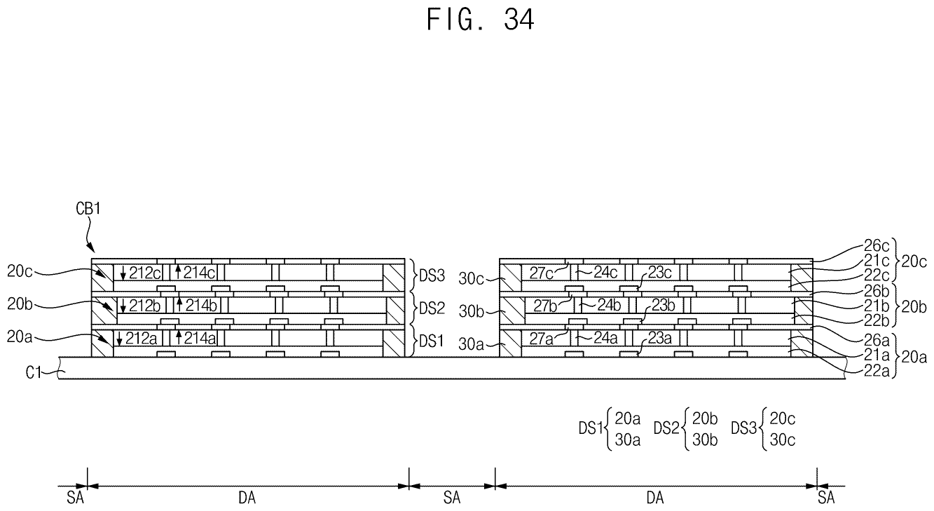

Referring to FIG. 34, processes the same as or similar to the processes described with reference to FIG. 17 may be performed to cut the stacked first to third die structures along a cutting region, that is, a scribe lane region, by a first sawing process to form individual core die blocks CB1 on the first carrier substrate C1.

Each of the core die blocks CB1 may include first, second and third die structures DS1, DS2 and DS3 sequentially stacked. Each of the first, second and third die structures DS1, DS2 and DS3 may include a core die 20 and a gap filling portion 30 that covers or surrounds an outer side surface of the core die 20. The core die block CB1 may include first, second and third core dies 20a, 20b and 20c, collectively 20, which are sequentially stacked, and first, second and third gap filling portions 30a, 30b and 30c, collectively 30 respectively covering or surrounding outer side surfaces of the first, second and third core dies 20a, 20b and 20c. In example embodiments, the core die block CB1 may include the core dies 20a, 20b, and 20c stacked in three stages, but it will be understood that the present inventive concept is not limited thereto.

Then, processes the same as or similar to the processes described with reference to FIGS. 18 to 22 may be performed to sequentially stack first to fifth core die blocks CB1, CB2, CB3, CB4, and CB5 and a top core die stack TD on a first wafer W1 including buffer dies.

Then, processes the same as or similar to the processes described with reference to FIG. 23 may be performed to form a molding member 40 on the first wafer W1 to at least partially fill gaps between the first, second, third, fourth and fifth core die blocks CB1, CB2, CB3, CB4, and CB5.

Then, portions of the first wafer W1 and the molding member 40 may be cut along a cutting region SA, that is, a scribe lane region by a second sawing process to complete the semiconductor package 101 of FIG. 24.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concept. Accordingly, all such modifications are intended to be included within the scope of example embodiments as defined in the claims.

What is claimed is:

1. A semiconductor package, comprising:
a buffer die;
a plurality of core die blocks sequentially stacked on the buffer die;
a top core die on an uppermost core die block of the plurality of core die blocks; and
a molding member surrounding outer side surfaces of the plurality of core die blocks and the top core die on the buffer die,
wherein each of the core die blocks includes:
a plurality of core dies sequentially stacked; and
a plurality of gap filling portions surrounding outer side surfaces of at least two stages of core dies of the plurality of core dies, and
wherein outer side surfaces of the plurality of gap filling portions of each of the plurality of core die blocks are coplanar.

2. The semiconductor package of claim 1, wherein an outer side surface of a first core die block among the plurality of core die blocks and an outer side surface of a second core die block stacked on the first core die block are positioned on different planes respectively.

3. The semiconductor package of claim 1, wherein each of the core dies includes:
a substrate;
a front insulating layer on a front surface of the substrate and having a first bonding pad therein; and
a backside insulating layer on a backside surface of the substrate and having a second bonding pad therein.

4. The semiconductor package of claim 3, wherein the backside insulating layer of a first core die among the plurality of core dies and the front insulating layer of a second core die stacked on the first core die are directly bonded to each other, and
the second bonding pad of the first core die and the first bonding pad of the second core die are directly bonded to each other.

5. The semiconductor package of claim 3, wherein each of the core dies further includes a through electrode that penetrates the substrate and is electrically connected to the first and second bonding pads.

6. The semiconductor package of claim 3, wherein the gap filling portion surrounds outer side surfaces of the substrate and the front insulating layer.

7. The semiconductor package of claim 6, wherein the backside insulating layer extends laterally along the backside surface of the substrate to cover an upper surface of the gap filling portion.

8. The semiconductor package of claim 1, wherein each of the core dies has a thickness within a range of about 10 μm to 30 μm.

9. The semiconductor package of claim 1, wherein the gap filling portion includes an inorganic dielectric or an organic dielectric.

10. The semiconductor package of claim 1, wherein the molding member is in direct contact with an outer side surface of a first stage of core die of the plurality of core dies.

11. A semiconductor package, comprising:
a buffer die;
a plurality of core die blocks sequentially stacked on the buffer die, each of the plurality of core die blocks including a plurality of die structures that are sequentially stacked; and
a sealing member surrounding outer side surfaces of the plurality of core die blocks on the buffer die,
wherein each of the plurality of die structures includes:
a substrate;
a front insulating layer on a front surface of the substrate and including a first bonding pad therein;
a backside insulating layer on a backside surface of the substrate and including a second bonding pad therein; and
a gap filling portion surrounding outer side surfaces of the substrate and the front insulating layer.

12. The semiconductor package of claim 11, wherein outer side surfaces of the gap filling portions of each of the core die blocks are coplanar.

13. The semiconductor package of claim 11, wherein an outer side surface of a first core die block among the plurality of core die blocks and an outer side surface of a second core die block stacked on the first core die block are positioned on different planes.

14. The semiconductor package of claim 11, wherein the backside insulating layer of a first die structure among the plurality of die structures and the front insulating layer of a second die structure stacked on the first die structure are directly bonded to each other, and
the second bonding pad of the first die structure and the first bonding pad of the second die structure are directly bonded to each other.

15. The semiconductor package of claim 11, wherein each of the die structures further includes a through electrode that penetrates the substrate and is electrically connected to the first and second bonding pads.

16. The semiconductor package of claim 11, wherein the backside insulating layer extends laterally along the backside surface of the substrate to cover an upper surface of the gap filling portion.

17. The semiconductor package of claim 11, wherein the gap filling portion includes an inorganic dielectric or an organic dielectric.

18. The semiconductor package of claim 11, wherein the sealing member includes a thermosetting resin.

19. The semiconductor package of claim 11, wherein the sealing member is in direct contact with the gap filling portions.

20. A semiconductor package, comprising:
a buffer die;
a plurality of core die blocks sequentially stacked on the buffer die; and
a sealing member on outer side surfaces of the plurality of core die blocks on the buffer die,
wherein each of the plurality of core die blocks includes:
a plurality of core dies sequentially stacked; and
a plurality of gap filling portions on outer side surfaces of at least two stages of core dies of the plurality of core dies.
